(19) United States
(12) Patent Application Publication
(10) Pub. No.: US 2026/0080827 A1
(43) Pub. Date: Mar. 19, 2026

(54) TFT STRUCTURES AND ELECTRICAL SIGNAL CONNECTIONS IN GOA AND PIXEL CIRCUITS FOR LCD AND OLED DISPLAYS

(71) Applicant: Applied Materials, Inc., Santa Clara, CA (US)

(72) Inventors: Jung Bae KIM, San Jose, CA (US); Dong Kil YIM, Pleasanton, CA (US); Soo Young CHOI, Fremont, CA (US); Yang Ho BAE, Santa Clara, CA (US); Rodney Shunleong LIM, Daly City, CA (US); Dejiu FAN, Santa Clara, CA (US); Milan PESIC, Paoli, PA (US); Bastien BELTRANDO, Marseille (FR)

(21) Appl. No.: 19/303,500

(22) Filed: Aug. 19, 2025

Related U.S. Application Data
(60) Provisional application No. 63/695,394, filed on Sep. 17, 2024.

(51) Int. Cl. G09G 3/3233; G09G 3/3266; G09G 3/36; H10K 59/121; H10K 59/131

(52) U.S. Cl. CPC G09G 3/3233; G09G 3/3266; H10K 59/1213; H10K 59/131; G09G 3/3648; G09G 2300/0408; G09G 2300/0852

(57) ABSTRACT

A circuit includes a switching thin film transistor (TFT), the switching TFT having a threshold voltage that is based on a value of the direct current (DC) voltage, a driving TFT coupled to the switching TFT, a storage capacitor disposed between the switching TFT and the driving TFT, and an organic light-emitting diode (OLED) having an anode coupled to the driving TFT.

### CROSS-REFERENCE TO RELATED APPLICATIONS

This application claims priority to U.S. Patent Application Ser. No. 63/695,394, filed Sep. 17, 2025, and assigned to the assignee hereof, the contents of each of which are hereby incorporated by reference in its entirety.

### BACKGROUND

### Field

Embodiments of the present disclosure generally relate to a thin film transistor (TFT) structures and circuits that include the TFT structures.

### Description of the Related Art

A thin-film transistor (TFT) is made by depositing thin films of an active semiconductor layer, as well as a dielectric layer and metallic contacts, over a supporting substrate, such as glass. In particular, a TFT can be a metal-oxide-semiconductor field-effect transistor (MOSFET).

TFTs have gained significant interest in display applications due to their high resolution, low power consumption, and high speed operation for liquid crystal displays (LCDs) and organic light-emitting diode (OLED) displays. TFTs are embedded within a panel of the display. Data line voltage signals from source driver ICs in display module and scan line voltage signals from gate driver circuits in peripheral display panel area in the display panel are delivered to TFTs in pixel circuits to control display images by turning on and off the TFTs in active display panel area. Image distortion is decreased by improving the response of the TFT with higher mobility and/or by reducing crosstalk between pixels. Most display products including LCD or OLED televisions (TVs) and monitors include TFTs in the panel. Many modern high-resolution and high-quality electronic visual display devices use active matrix based OLED displays with a large number of TFTs as components of pixel circuits. One beneficial aspect of TFT technology is its use of a separate TFT for each pixel on the display. Each TFT works as a switch or a source of current in the pixel circuit or gate driver circuit by controlling voltage and current through data and gate signal lines for increased control of display images. Higher on current from a high mobility TFT allows fast refresh of the display images and better image qualities by minimizing the distortion of data and gate signal voltages.

One drawback of conventional TFTs for OLED display panels is that the TFTs can have limitations on the stability, voltage control for color and/or gray scale, high sensitivity with drain voltage from driving TFT as a component of pixel circuit for the control of OLED current control due to the OLED uniformity changes due to the on-current variations in driving TFT during display operation, and slow speed of response in switching TFTs as a component of pixel circuit, especially for high resolution and/or large screen displays.

Therefore, what is needed are improved switching and driving TFTs for pixel circuits and improved switching TFTs for gate driver circuits with low off leakage current and improved stability.

### SUMMARY

According to one or more embodiments, a circuit includes a switching thin film transistor (TFT), the switching TFT having a threshold voltage that is based on a value of a direct current (DC) voltage, a driving TFT coupled to the switching TFT, a storage capacitor disposed between the switching TFT and the driving TFT, and an organic light-emitting diode (OLED) having an anode coupled to the driving TFT.

According to one or more embodiments, a circuit includes a first switching thin film transistor (TFT), a second switching TFT, the second switching TFT having a threshold voltage that is based on a value of a direct current (DC) voltage, a driving TFT coupled to the first switching TFT and the second switching TFT, a first storage capacitor having a first side that is coupled to a first node disposed between the second switching TFT and the driving TFT, and an organic light-emitting diode (OLED) having an anode coupled to the driving TFT.

According to one or more embodiments, a circuit includes a switching TFT, the switching TFT having a threshold voltage that is based on a value of the direct current (DC) voltage, a loading capacitor coupled to the switching TFT; and a storage capacitor coupled to the switching TFT.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic of a simplified organic light emitting diode display (OLED) panel 100, according to one or more embodiments.

FIG. 2 is a schematic of an active matrix pixel array in the display area 104 of an OLED panel 100, according to one or more embodiments.

FIGS. 3A-3D illustrate a schematic, cross-sectional view of thin film transistor (TFT) structures that can be utilized in gate driver on array (GOA) and/or pixel circuits, according to one or more embodiments.

FIGS. 4A-4B illustrate a schematic, cross-sectional view of thin film transistor (TFT) having electrical connections in a first configuration that can be utilized in GOA and/or pixel circuits, according to one or more embodiments.

FIGS. 5A-5B illustrate a schematic, cross-sectional view of thin film transistor (TFT) having electrical connections in a second configuration that can be utilized in GOA and/or pixel circuits, according to one or more embodiments.

FIGS. 6A-6B illustrate a schematic, cross-sectional view of thin film transistor (TFT) having electrical connections in a third configuration that can be utilized in GOA and/or pixel circuits, according to one or more embodiments.

FIGS. 7A-7B illustrate a schematic, cross-sectional view of thin film transistor (TFT) having electrical connections in a fourth configuration that can be utilized in GOA and/or pixel circuits, according to one or more embodiments.

FIGS. 8A-8B illustrate a schematic, cross-sectional view of thin film transistor (TFT) having electrical connections in a fifth configuration that can be utilized in GOA and/or pixel circuits, according to one or more embodiments.

FIGS. 9A-9B illustrate a schematic, cross-sectional view of thin film transistor (TFT) having electrical connections in a sixth configuration that can be utilized in GOA and/or pixel circuits, according to one or more embodiments.

FIG. 10 depicts a graphical illustration of drain-to-source current versus the gate voltage for different DC voltages for of a TFT, according to one or more embodiments.

FIG. 11 depicts a graphical illustration of the drain-to-source current versus the gate voltage for different DC voltages for of a TFT, according to one or more embodiments.

FIG. 12A is a schematic of the organic light emitting diode display (OLED) panel according to one or more embodiments.

FIGS. 12B-12C are schematic illustrations of GOA circuits according to one or more embodiments.

FIGS. 13A-13B are schematic illustrations of a subpixel circuits, according to one or more embodiments.

FIGS. 14A-14B are schematic illustrations of a subpixel circuits, according to one or more embodiments.

FIGS. 15A-15D are schematic illustrations of a subpixel circuits, according to one or more embodiments.

FIGS. 16A-16B are schematic illustrations of a subpixel circuits, according to one or more embodiments.

FIGS. 17A-17G are schematic illustrations of a subpixel circuits, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The following detailed description is merely exemplary in nature and is not intended to limit the disclosure or the application and uses of the disclosure. Furthermore, there is no intention to be bound by any expressed or implied theory presented in the preceding background, summary, or the following detailed description.

Embodiments herein include thin-film transistors (TFTs) used in circuits for devices, such as display devices and electrical signal connections for gate driver on array (GOA) circuits and pixel circuits for liquid crystal displays (LCDs) and organic light-emitting diode (OLED) displays. The TFTs disclosed herein transport high current with high stability, good control, and fast response of the TFTs due to higher on current in the TFTs, and selection of electrodes to apply biasing in combination with selection of electrodes to connect for each circuit. The TFTs described herein can be used as driving TFTs for pixel circuits as well as switching TFTs for GOA circuits and pixel circuits. One or more of the TFTs include a gate structure disposed over a high carrier density metal oxide channel. The gate structure includes one or more gate electrodes, and thus the TFTs are top-gate (TG), double-gate (DG), or bottom-gate (BG) TFTs. The TFTs described herein are particularly useful for single and/or double-gate structures. The channel can include one or more layers of differing electron mobilities contributing different benefits to each TFT. In particular, high mobility layers of the channel increases the speed of response of the TFTs, and low mobility layers allow more positive threshold voltage (turn on voltage) and lower leakage current than a high mobility layer in the same TFTs. The combination of the low mobility layer and the high mobility layer results in TFTs with improved qualities such as improved mobility, lower off leakage current, and positive threshold voltage (turn on voltage), as described herein.

In order to operate a subpixel of an OLED pixel for a display, at least one switching TFT, one driving TFT, and one capacitor are used. The switching TFT passes data voltage to the capacitor (storage). The storage capacitor is connected to a gate for a driving TFT. The gate voltage of the driving TFT connected to the storage capacitance determines how much current of the driving TFT is flowing to the OLED to control brightness. The required capacitance of the storage capacitor is determined by the frame rate and the leakage current of the switching TFT connected to both the storage capacitor and the gate of the driving TFT for the display.

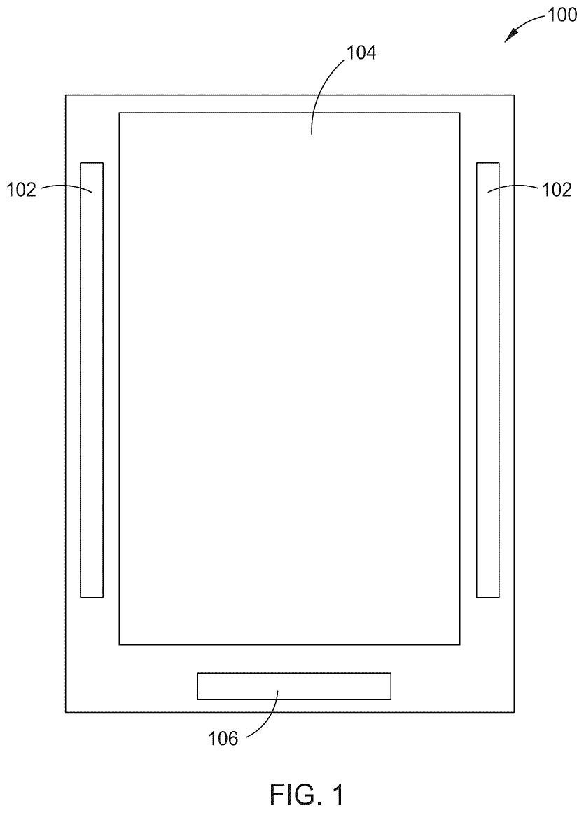

FIG. 1 is a schematic of a simplified organic light emitting diode display (OLED) panel 100, according to one or more embodiments. The OLED panel 100 includes a non-display area 102 of switching TFTs for a gate driver on array (GOA) circuit, a display area 104 of switching and driving TFTs for pixel circuit, and a control area 106 including one or more circuits including, but not limited to, source (data) driver integrated circuits and/or a display module printed circuit board (PCB). In some aspects, the non-display area 102 is disposed in an edge region disposed at one or more sides, or surrounding the display area 104.

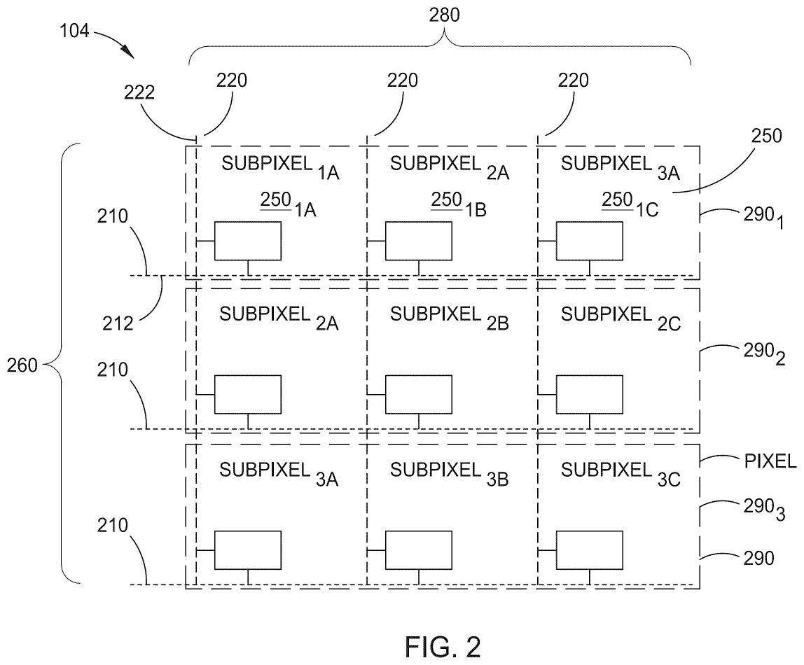

FIG. 2 is a schematic of an active matrix pixel array in the display area 104 of an OLED panel 100, according to one or more embodiments. The display area 104 has an array of pixels 290, i.e., a first pixel 290₁, a second pixel 290₂, a third pixel 290₃, etc., arranged in rows 260 and columns 280. Each pixel 290 has a plurality of subpixels 250 for determining a value of the pixel 290. For example, a first pixel 290₁ has a first subpixel 250_{1A}, a second subpixel 250_{1B} and a third subpixel 250_{1C}. Each subpixel 250 being a single color element of a respective pixel 290. However, the first pixel 290₁ may have more than three subpixels 250, for example, a subpixel 250_{1N} wherein ‘1N’ can represent any number of subpixels 250 for the first pixel 290₁. Each row 260 in the OLED panel 100 can be accessed independently using scan lines 210. Each column 280 in the OLED panel 100 can be accessed using data lines 220. Addressing a first scan line 212 and a first data line 222 accesses the first subpixel 250_{1A} in the first pixel 290₁ of the OLED panel 100. Each subpixel 250 may be similarly addressed in the OLED panel 100. In various embodiments, while each subpixel 250 is illustrated as being coupled to a single scan line 210, each subpixel may be coupled to a plurality of scan lines 210 that may be used to control updating each subpixel 250. In such embodiments, the scan lines 210 may be driven at different times with different select signals to control the update timing of the subpixels 250.

In one or more embodiments, the OLED panel 100 may be an organic light emitting diode (OLED) display device. In such an embodiment, each of the subpixels 250 may comprise an electrode that is coupled to a corresponding scan line (or lines) and a data line via one or more transistors. A subpixel data signal (or signals) is applied to a switching TFT to deliver data signal to a driving TFT with a specified voltage level when the switching TFT is turned on. The driving TFT are connected to OLED and the current from the driving TFT controls the brightness of OLED in OLED display panel. The supply voltages, ELVDD or VSS, are applied to each subpixel to control gray scale color and brightness of OLED by controlling the current in driving TFT in each pixels. In one embodiment, a positive supply voltage may be referred to as ELVDD and a negative supply voltage may be referred to as VSS or ELVSS.

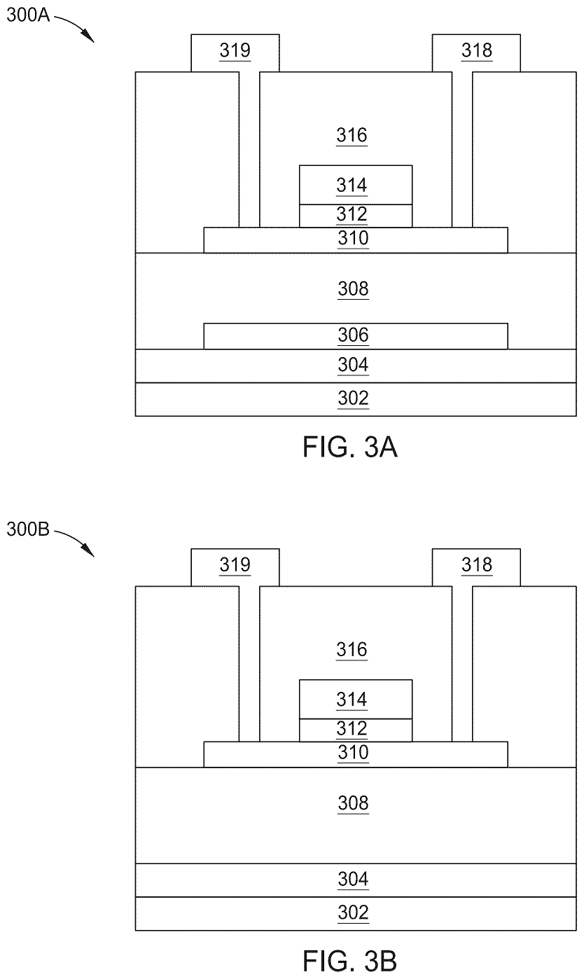

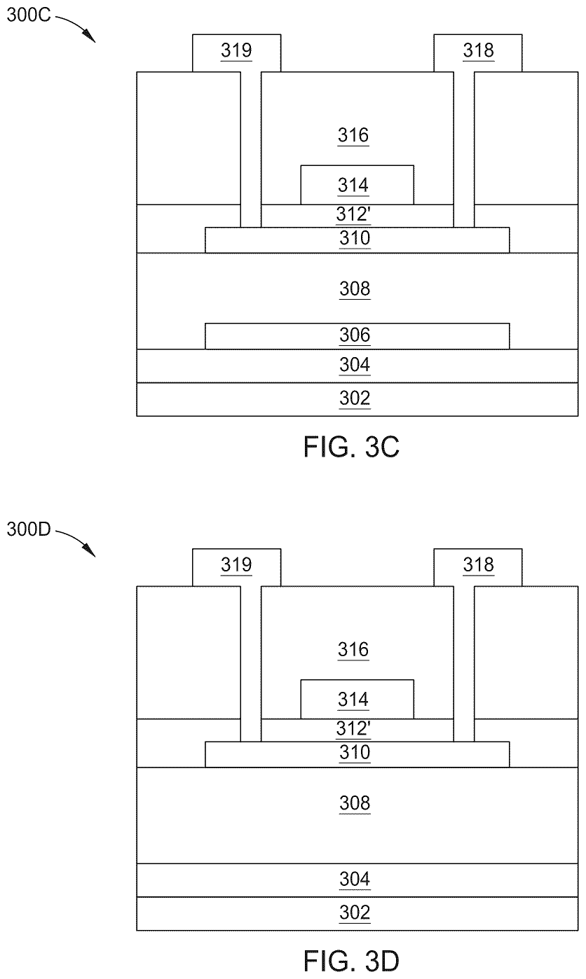

FIGS. 3A-3D illustrate a schematic, cross-sectional view of thin film transistor (TFT) structures that can be utilized in GOA and/or pixel circuits, according to one or more embodiments.

As illustrated in FIG. 3A a first TFT structure 300A (also referred to as a type-A TFT structure) includes a substrate 302 such as a silicon based substrate, an insulating based substrate, a germanium based substrate, or other suitable flexible substrate. The substrate 302 may include one or more generic layers that would be present in a complementary metal-oxide-semiconductor (CMOS) device structure. The substrate 302 can include a transparent material, such as a rigid glass or flexible polyimides (PI), which can be useful if the TFT is used in LCD or OLED display applications, such as TVs, tablets, laptops, mobile phones or other displays.

In some embodiments, a buffer layer 304 is disposed over the substrate 302, such as in direct contact with the substrate 302. The buffer layer 304 can include insulating materials such as single silicon dioxide (SiOₓ), silicon nitride (SiNₓ), multi-layer silicon nitride/silicon oxide (SiNₓ/SiO_{y}), silicon oxynitride (SiON), other insulating materials, or combinations thereof. The back gate electrode 306 is disposed over the buffer layer 304. In some aspects the back gate electrode 306 is deposited and patterned using any suitable process known in the industry. A back gate insulating (GI) layer 308 is disposed over and surrounds the back gate electrode 306. The GI material for the back GI layer 308 and/or for any gate insulators described herein can include insulating materials such as silicon, SiNₓ, other insulating materials, or combinations thereof, such as silicon di-oxide (SiO2), polymethylsilsesquioxane (PMSQ) or other suitable material.

A channel structure 310 is disposed over the bottom GI layer 308. The channel structure 310 can be a single layer channel structure, a double layer channel stack with each layer having different electron mobility, or three or more layers, each layer having different electron mobility than layers disposed immediately above or below the layer. The channel structure 310 is composed of a metal oxide material, or low temperature poly silicon (LTPS). Any of the channel structures described herein can be composed of a metal oxide (MO) material, such a single or multi-layer MO channel. Alternatively, any of the channel structures described herein can be composed of LTPS, such as a single layer LTPS channel. The metal oxide can include oxygen (O), indium (In), gallium (Ga), zinc (Zn), tin (Sn), aluminum (Al), and combination(s) thereof, such as In—Zn—O, In—Ga—O, In—Sn—O, In—Ga—Zn—O, In—Zn—Sn—O, In—Ga—Sn—O, In—Ga—Zn—Sn—O, or any combination(s) thereof. The metal oxide materials or LTPS can be selected based on a predetermined electron mobility selected for one or more layer of the channel structure 310. A top gate insulating (GI) layer 312 is disposed over the channel structure 310. The first TFT structure 300A includes a top GI layer 312 is that is patterned to approximate a width of a top gate electrode 314 disposed above the top GI layer 312.

An inter layer dielectric (ILD) layer 316 is disposed over the top gate electrode 314 and a portion of the channel structure 310. Any ILD layer described herein may be composed of a material such as silicon oxides, nitrides, oxynitrides, and carbides such as silicon-based dielectric films.

In one or more embodiments, a source electrode 318 and a drain electrode 319 are disposed over the ILD layer 316. The source electrode 318 and drain electrode 319 are coupled to vias in the ILD layer 316 to the channel structure 310. Each electrode described herein (e.g., top gate electrode 314, back gate electrode 306, source/drain electrodes 318, 319) include conductive materials such as molybdenum (Mo), chromium (Cr), copper (Cu), titanium (Ti), tantalum (Ta), tungsten (W), alloy metals including MoW, combinations of conductive materials including MoW, TiCu, MoCu, MoCuMo, TiCuTi, MoWCu, MoWCuMoW, any electrically conductive materials, such as including conductive metal oxides, such as indium tin oxide (InSnO) [ITO] and indium zinc oxide (InZnO) [IZO], or any combination thereof.

As illustrated in FIG. 3B a second TFT structure 300B (also referred to as a type-B TFT structure) includes the substrate 302, the buffer layer 304, the bottom GI layer 308, the channel structure 310, the top GI layer 312, the top gate electrode 314, the ILD layer 316, the source electrode 318 and the drain electrode 319. Stated otherwise, the second TFT structure 300B differs from the first TFT structure 300A because the second TFT structure 300B does not include a back gate electrode 306.

As illustrated in FIG. 3C, a third TFT structure 300C (also referred to as a type-C TFT structure) includes the substrate 302, the buffer layer 304, the back gate electrode 306 the bottom GI layer 308, the channel structure 310, a top GI layer 312′, the top gate electrode 314, the ILD layer 316, the source electrode 318 and the drain electrode 319. The top GI layer 312′ has a width greater than the top gate electrode 314. Stated otherwise, the third TFT structure 300C is similar to the first TFT structure 300A, except that the top GI layer 312′ has a width greater than the top gate electrode 314 (i.e., is not etched).

As illustrated in FIG. 3D, a fourth TFT structure 300D (also referred to as a type-D TFT structure) includes the substrate 302, the buffer layer 304, the bottom GI layer 308, the channel structure 310, a top GI layer 312′, the top gate electrode 314, the ILD layer 316, the source electrode 318 and the drain electrode 319. The top GI layer 312′ has a width greater than the top gate electrode 314. Stated otherwise, the fourth TFT structure 300D is similar to the second TFT structure 300B, except that the top GI layer 312′ has a width greater than the top gate electrode 314 (e.g., is not etched).

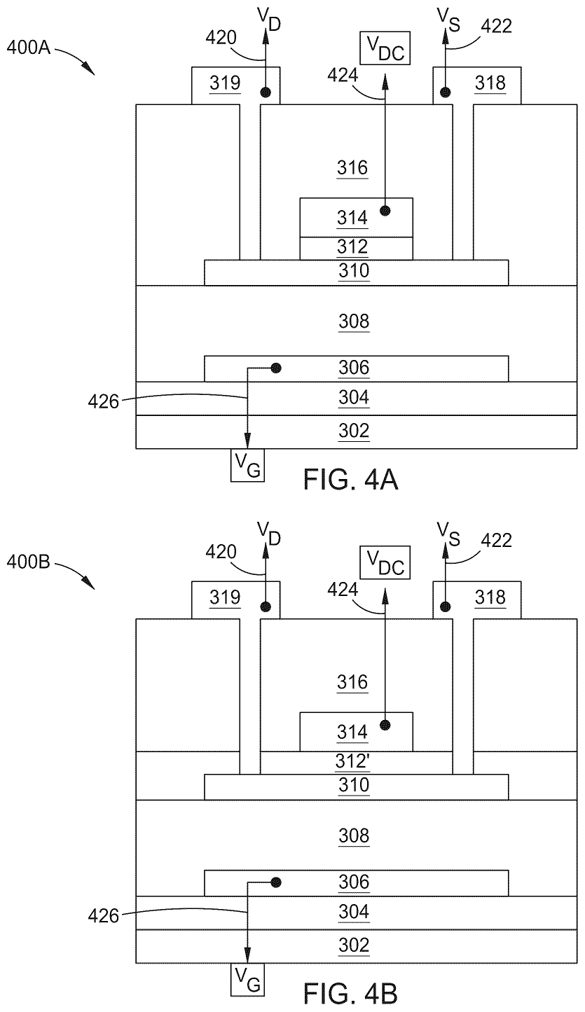

FIGS. 4A-4B illustrate a schematic, cross-sectional view of thin film transistor (TFT) having electrical connections in a first configuration that can be utilized in GOA and/or pixel circuits, according to one or more embodiments.

In one or more embodiments, a TFT having electrical connections in a first configuration (defined herein as a “type1 TFT”) may be formed on TFT structure that includes a back gate electrode 306. As illustrated in FIG. 4A, a type1 TFT may be formed on the first TFT structure 300A and may defined herein as a type1-A TFT 400A. As illustrated in FIG. 4B, a type1 TFT may be formed on the third TFT structure 300C and may be defined herein as a type1-C TFT 400B.

For example, a type1-A TFT 400A and a type1-C TFT 400B include a drain electrode path 420 coupled to drain voltage V_{D}, source electrode path 422 coupled to source voltage V_{S}, top gate electrode path 424 coupled to a DC (direct current) voltage source V_{DC} (also referred to herein as “a DC voltage V_{DC}”), and back gate electrode path 426 coupled to gate voltage V_{G}. In some embodiments, the connections are connected by electrical wiring and/or other connection bridges. The connection can be made using contact holes in the active pixel area (e.g., display area 104). The DC voltage V_{DC} (i.e., a DC bias voltage) is applied via the top gate electrode path 424 to the top gate electrode 314. The gate voltage V_{G} is applied via back gate electrode path 426 to the back gate electrode 306.

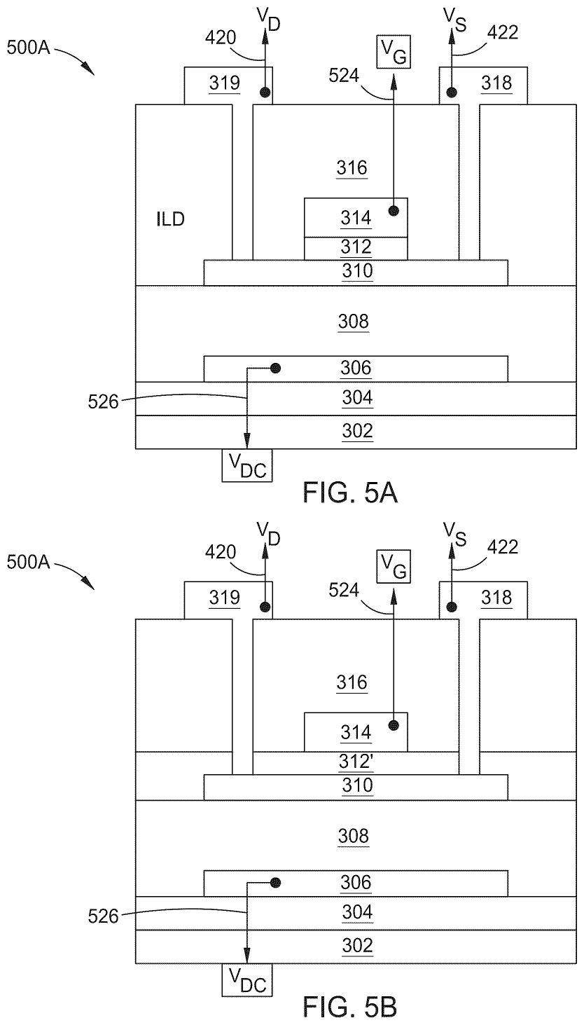

FIGS. 5A-5B illustrate a schematic, cross-sectional view of thin film transistor (TFT) having electrical connections in a second configuration that can be utilized in GOA and/or pixel circuits, according to one or more embodiments.

In one or more embodiments, a TFT having electrical connections in a second configuration (defined herein as a “type2 TFT”) may be formed on TFT structure that includes a back gate electrode 306. As illustrated in FIG. 5A, a type2 TFT may be formed on the first TFT structure 300A and may be defined herein as a type2-A TFT 500A. As illustrated in FIG. 5B, a type2 TFT may be formed on the third TFT structure 300C and may be defined herein as a type2-C TFT 500B.

For example, a type2-A TFT 500A and a type2-C TFT 500B include the drain electrode path 420 and the source electrode path 422. The type2-A TFT 500A and the type2-C TFT 500B may include a top gate electrode path 524 coupled to the gate voltage V_{G}, and a back gate electrode path 526 coupled to the DC voltage V_{DC}. In some embodiments, the connections are connected by electrical wiring and/or other connection bridges. The connection can be made using contact holes in the active pixel area (e.g., display area 104). The gate voltage V_{G} is applied via top gate electrode path 524 to the top gate electrode 314.

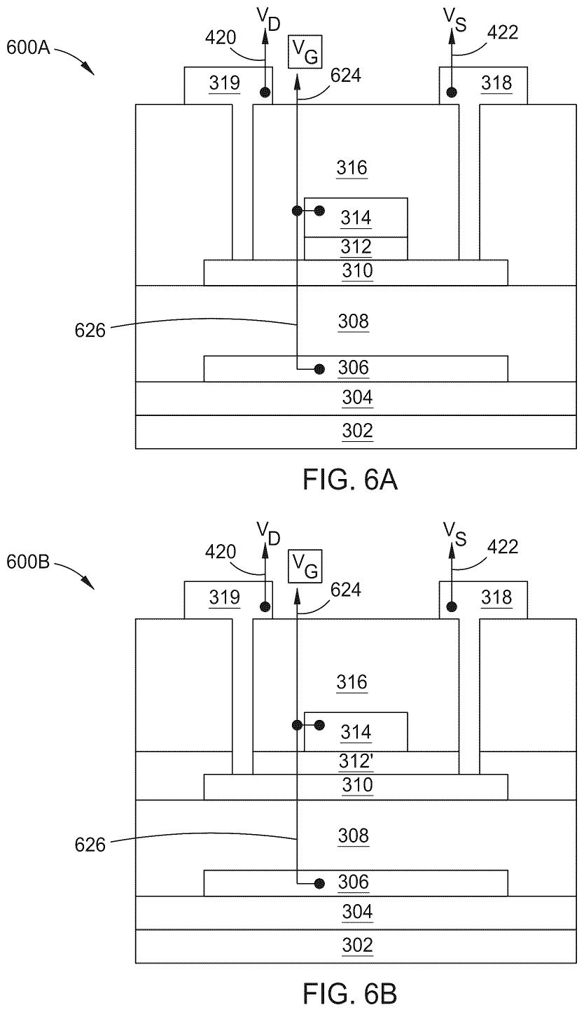

FIGS. 6A-6B illustrate a schematic, cross-sectional view of thin film transistor (TFT) having electrical connections in a third configuration that can be utilized in GOA and/or pixel circuits, according to one or more embodiments.

In one or more embodiments, a TFT having electrical connections in a third configuration (defined herein as a “type3 TFT”) may be formed on TFT structure that includes the back gate electrode 306. As illustrated in FIG. 6A, a type3 TFT may be formed on the first TFT structure 300A and may defined herein as a type3-A TFT 600A. As illustrated in FIG. 6B a type3 TFT may be formed on the third TFT structure 300C and may be defined herein as a type3-C TFT 600B.

For example, a type3-A TFT 600A and a type3-C TFT 600B include the drain electrode path 420 and the source electrode path 422. The type3-A TFT 600A and the type3-C TFT 600B may include a top gate electrode path 624 and a back gate electrode path 626 that are both coupled to the gate voltage V_{G}. In some embodiments, the connections are connected by electrical wiring and/or other connection bridges. The connection can be made using contact holes in the active pixel area (e.g., display area 104). The gate voltage V_{G} is applied via the top gate electrode path 624 to the top gate electrode 314 and to the back gate electrode 306 via the back gate electrode path 626.

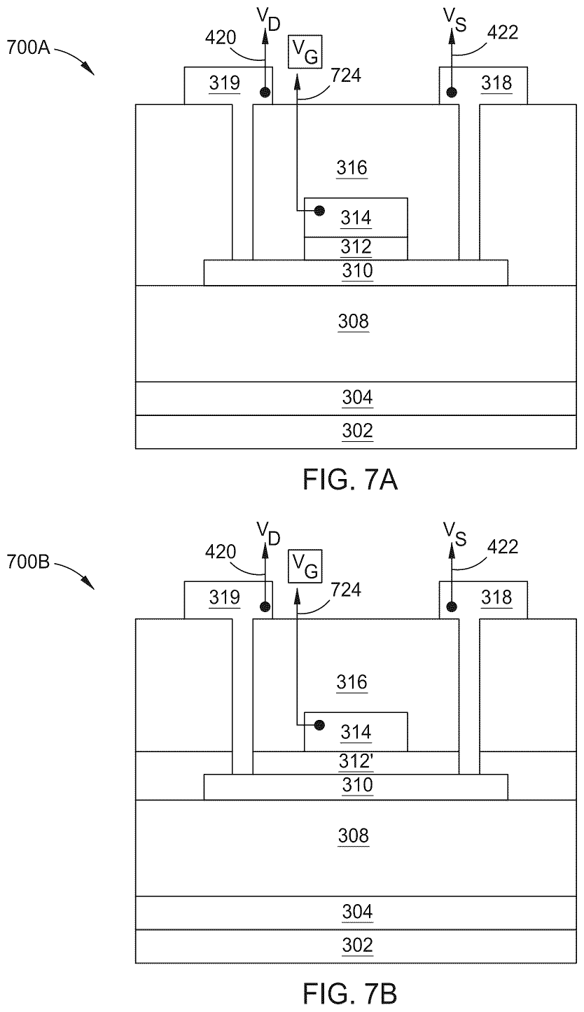

FIGS. 7A-7B illustrate a schematic, cross-sectional view of thin film transistor (TFT) having electrical connections in a fourth configuration that can be utilized in GOA and/or pixel circuits, according to one or more embodiments.

In one or more embodiments, a TFT having electrical connections in a fourth configuration (defined herein as a “type4 TFT”) may be formed on TFT structure that does not include the back gate electrode 306. As illustrated in FIG. 7A, a type4 TFT may be formed on the second TFT structure 300B and may be defined herein as a type4-B TFT 700A. As illustrated in FIG. 7B, a type4 TFT may be formed on the fourth TFT structure 300D and may be defined herein as a type4-D TFT 700B.

For example, a type4-B TFT 700A and a type4-D TFT 700B include the drain electrode path 420 and the source electrode path 422. The type4-B TFT 700A and the type4-D TFT 700B may include a top gate electrode path 724 coupled to the gate voltage V_{G}. In some embodiments, the connections are connected by electrical wiring and/or other connection bridges. The connection can be made using contact holes in the active pixel area (e.g., display area 104). A gate voltage V_{G} is applied via top gate electrode path 724 to the top gate electrode 314.

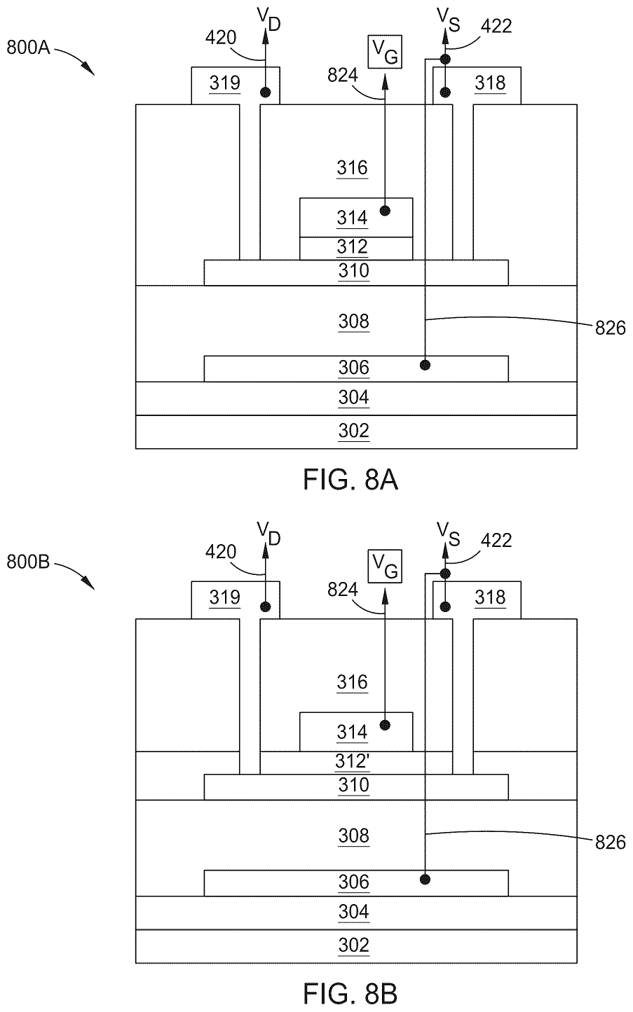

FIGS. 8A-8B illustrate a schematic, cross-sectional view of thin film transistor (TFT) having electrical connections in a fifth configuration that can be utilized in GOA and/or pixel circuits, according to one or more embodiments.

In one or more embodiments, a TFT having electrical connections in a fourth configuration (defined herein as a “type5 TFT”) may be formed on TFT structure that includes a back gate electrode 306. As illustrated in FIG. 8A, a type5 TFT may be formed on the first TFT structure 300A and may be defined herein as a type5-A TFT 800A. As illustrated in FIG. 8B a type5 TFT may be formed on the third TFT structure 300C and may be defined herein as a type5-C TFT 800B.

For example, a type5-A TFT 800A and a type5-C TFT 800B include the drain electrode path 420 and the source electrode path 422. The type5-A TFT 800A and the type5-C TFT 800B may include a top gate electrode path 824 coupled to the gate voltage V_{G} and a back gate electrode path 826 coupled to the source electrode path 422. The source voltage V_{S} may be applied to the back gate electrode 306 via back gate electrode path 826. The gate voltage V_{G} is applied via top gate electrode path 824.

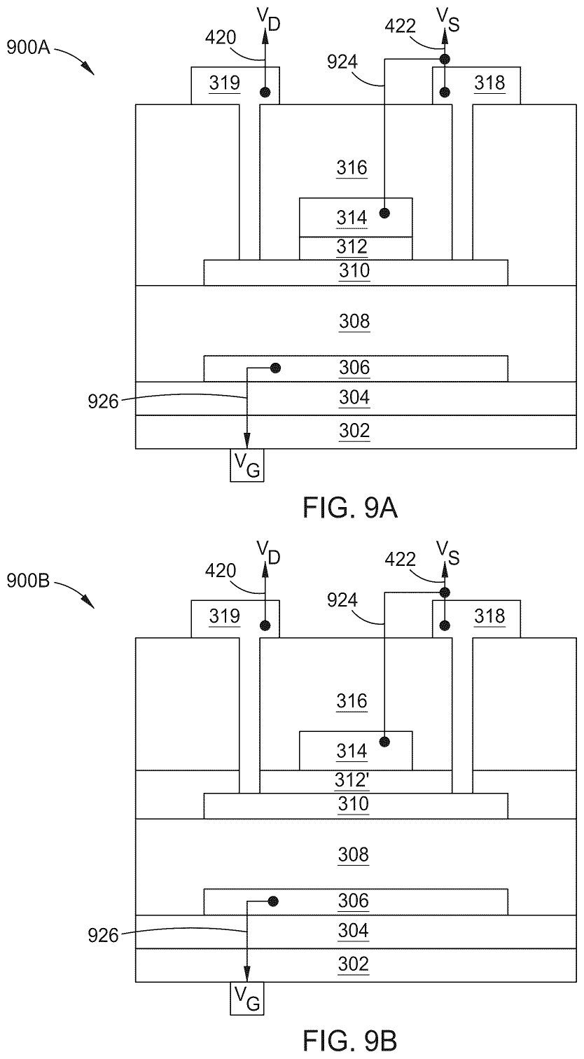

FIGS. 9A-9B illustrate a schematic, cross-sectional view of thin film transistor (TFT) having electrical connections in a sixth configuration that can be utilized in GOA and/or pixel circuits, according to one or more embodiments.

In one or more embodiments, a TFT structure having electrical connections in a sixth configuration (defined herein as a “type6 TFT”) may be formed on TFT structure that includes a back gate electrode 306. As illustrated in FIG. 9A, a type6 TFT may be formed on the first TFT structure 300A and may defined herein as a type6-A TFT 900A. As illustrated in FIG. 9B, a type6 TFT may be formed on the third TFT structure 300C and may be defined herein as a type6-C TFT 900B.

For example, a type6-A TFT 900A and a type6-C TFT 900B include the drain electrode path 420 and the source electrode path 422. The type6-A TFT 900A and the type6-C TFT 900B may include a top gate electrode path 924 coupled to the source electrode path 422 and a back gate electrode path 926 coupled to the gate voltage V_{G}. The source voltage V_{S} may be applied to the top gate electrode 314 via top gate electrode path 924. The gate voltage V_{G} is applied via back gate electrode path 926 to the back gate electrode 306.

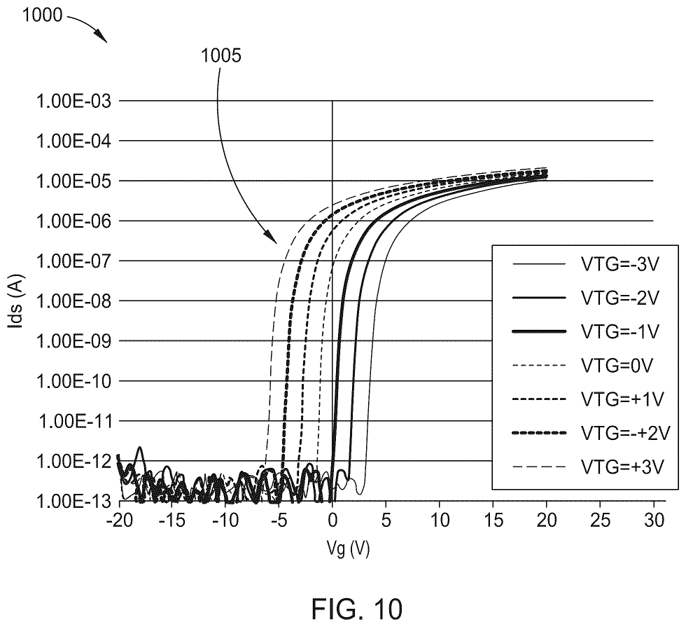

FIG. 10 depicts a graphical illustration 1000 of drain-to-source current las versus the gate voltage V_{G} for different DC voltages V_{DC} for of a TFT, according to one or more embodiments. In particular, graphical illustration 1000 illustrates a set of transfer curves 1005 that illustrate the relationship between the drain-to-source current I_{ds} and gate voltage V_{G} for a TFT structure having electrical connections in the first configuration (i.e., a type1-A TFT 400A or a type1-C TFT 400B) based on different top gate voltages V_{TG}. As shown in FIGS. 4A-4B, the gate voltage V_{G} is the voltage applied to the back gate electrode 306 of a type1 TFT.

Referring back to FIG. 10, the threshold voltage Vₜₕ of a type1 TFT can be controlled based on the top gate voltage V_{TG} that is supplied to the top gate electrode 314. In the case of a type1 TFT, the top gate voltage V_{TG} is the DC voltage V_{DC} (FIGS. 4A-4B). As shown in FIG. 10, as the DC voltage V_{DC} is changed from 3V to −3V, the threshold voltage Vₜₕ increases and changes from a negative to a positive voltage. The DC voltage V_{DC} can be used to control the threshold voltage Vₜₕ voltage to change the threshold voltage Vₜₕ to be positive (or vice versa) while remaining as close to zero as possible. The DC voltage V_{DC} may be changed based on the initial threshold voltage Vₜₕ (i.e., design) of the type1 TFT. For example, the more negative the initial threshold voltage Vin, the more the DC voltage V_{DC} needs to be decreased (i.e., changed in the negative direction). In another example, if the initial threshold voltage Vₜₕ is too high (to far positive) the DC voltage V_{DC} needs to be increased (i.e., changed in the positive direction). For example, for the type1 TFT of graphical illustration 1000, the DC voltage V_{DC} can be set to −1V for a positive threshold voltage Vₜₕ that is close to zero. In other examples, other DC voltage V_{DC} values may be used to tune the threshold voltage Vₜₕ. Advantageously, as illustrated by the transfer curves, the DC voltage V_{DC} can be tuned to reduce the operating current (i.e., the Ids) when the gate voltage V_{G} is equal to zero, generate a positive threshold voltage Vₜₕ without sacrificing stability due to the addition of the back gate electrode 306, and reduce the leakage current.

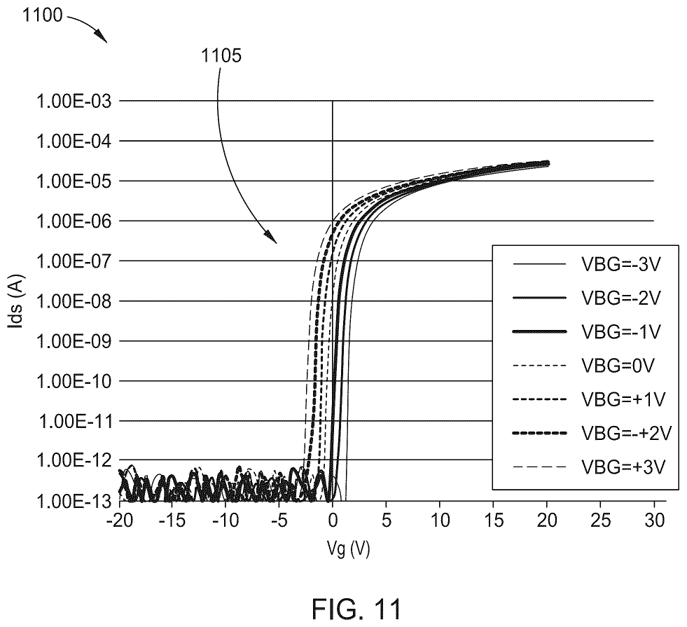

FIG. 11 depicts a graphical illustration 1100 of the drain-to-source current I_{ds} versus the gate voltage V_{G} for different DC voltages V_{DC} for of a TFT, according to one embodiment. In particular, graphical illustration 1100 illustrates a set of transfer curves 1105 that illustrate the relationship between the drain-to-source current I_{ds} and gate voltage V_{G} for a TFT structure having electrical connections in the second configuration (i.e., a type2-A TFT 500A or a type2-C TFT 500B) based on different back gate voltages V_{BG}. As shown in FIGS. 5A-5B, the gate voltage V_{G} is the voltage applied to the top gate electrode 314 of a type2 TFT.

Referring back to FIG. 11, the threshold voltage Vₜₕ of a type2 TFT can be controlled based on the back gate voltage V_{BG} that is supplied to the back gate electrode 306. In the case of a type2 TFT, the back gate voltage V_{BG} is the DC voltage V_{DC} (FIGS. 5A-5B). As shown in FIG. 11, as the DC voltage V_{DC} is changed from 3V to −3V, the threshold voltage Vₜₕ increases and changes from a negative to a positive voltage. The DC voltage V_{DC} can be used to control the threshold voltage Vₜₕ voltage to change the threshold voltage Vₜₕ to be positive (or vice versa) while remaining as close to zero as possible. The DC voltage V_{DC} may be changed based on the initial threshold voltage Vₜₕ (i.e., design) of the type2 TFT. For example, the more negative the initial threshold voltage Vₜₕ the more the DC voltage V_{DC} needs to be decreased (i.e., changed in the negative direction). In another example, if the initial threshold voltage Vₜₕ is too high (to far positive) the DC voltage V_{DC} needs to be increased (i.e., changed in the positive direction). For example, for the type2 TFT of graphical illustration 1100, the DC voltage V_{DC} can be set to −1V for a positive threshold voltage Vₜₕ that is close to zero. In other examples, other DC voltage V_{DC} values may be used to tune the threshold voltage Vₜₕ. Advantageously, as illustrated by the transfer curves, the DC voltage V_{DC} can be tuned to reduce the operating current (i.e., the I_{ds}) when the gate voltage V_{G} is equal to zero, generate a positive threshold voltage Vₜₕ without sacrificing stability due to the addition of the back gate electrode 306, and reduce the leakage current. Stated otherwise, the threshold voltage of type1 and type2 TFTs, which may be used as driving TFTs in subpixel circuits can be tuned by changing the value of the DC voltage.

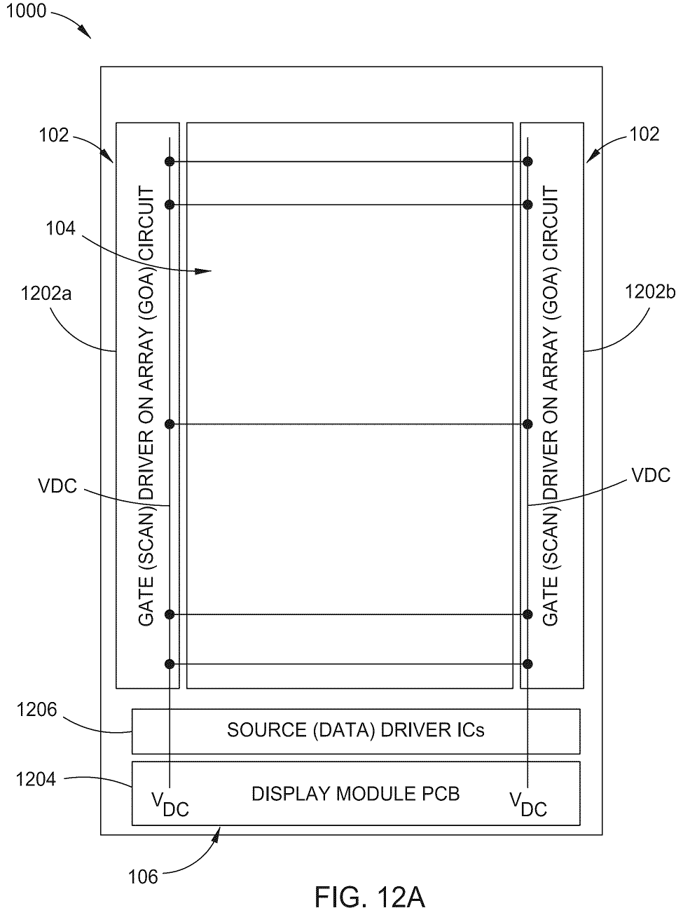

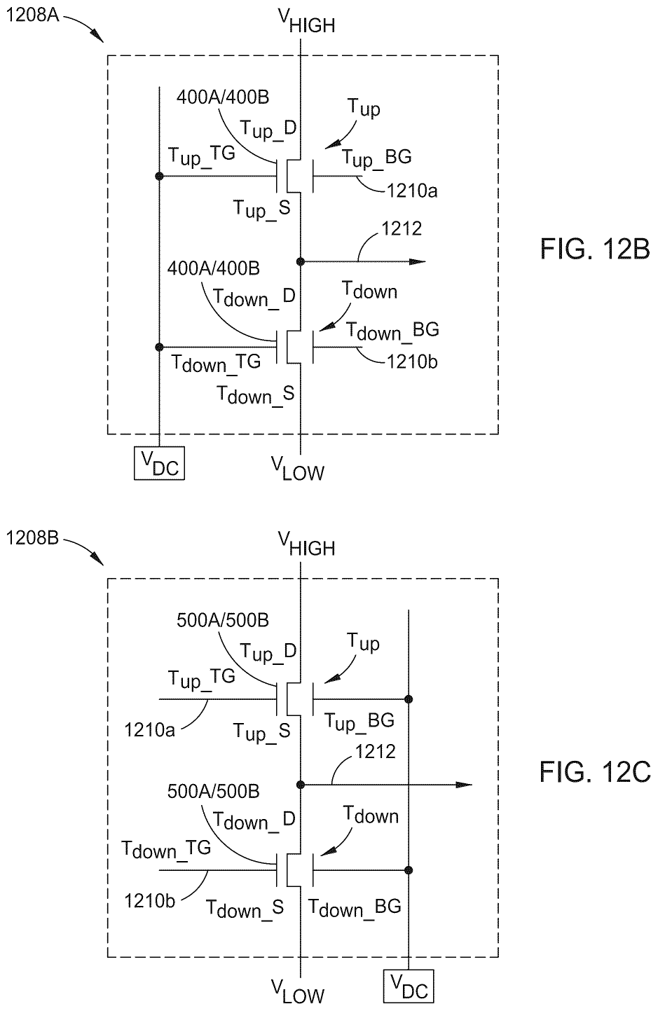

FIG. 12A is a schematic of the organic light emitting diode display (OLED) panel 100 according to one or more embodiments. As noted above, in one or more embodiments, the OLED panel 100 may include non-display areas 102 disposed in an edge region on both sides of the display area 104, and control area 106. In one or more embodiments, the control area 106 includes a source (data) driver integrated circuit 1206 and a display module printed circuit board (PCB) 1204. In one or more embodiments, the non-display areas 102 on both sides of the display area include GOA circuits. For example, the non-display areas 102 include a first GOA circuit 1202a and a second GOA circuit 1202b. Both of the GOA circuits are coupled to and configured to provide an output to subpixel circuits included in the display area 104. In one or more examples, the output of the GOA circuits are provided to subpixel circuits included in the subpixels 250 that make up the display area 104 via scan lines (e.g., V_{Scan1} and V_{Scan2} described below). In one or more examples, the second GOA circuit 1202b is optional. The first GOA circuit 1202a and the second GOA circuit 1202b each include a plurality of transistors (TFTs) that operate as switching TFTs. For example, the first GOA circuit 1202a and the second GOA circuit 1202b include a pull-up switching TFT and a pull-down switching TFT. Both switching TFTs may be either type1 TFTs or type2 TFTs. The first GOA circuit 1202a and the second GOA circuit 1202b are configured to receive the DC voltage V_{DC} from either of the source (data) driver integrated circuit 1206 and a display module PCB 1204. In the same manner described above, the DC voltage V_{DC} is used to control the threshold voltage of the switching TFTs. The first GOA circuit 1202a and the second GOA circuit 1202b may be the same circuit.

FIGS. 12B-12C are schematic illustrations of GOA circuits according to one or more embodiments. FIG. 12B illustrates a schematic illustration of a GOA circuit 1208a according to one or more embodiments. The first GOA circuit 1202a and the second GOA circuit 1202b may be GOA circuit 1208a. The GOA circuit includes a pull-up transistor T_{UP} coupled to a pull-down transistor T_{DOWN}. The pull-up transistor T_{UP} and the pull-down transistor T_{DOWN} may be the same type of transistor.

In one or more embodiments, the pull-up transistor T_{UP} may include a drain electrode T_{UP}_D, a source electrode T_{UP}_S, a top gate electrode T_{UP}_TG, and a back gate electrode T_{UP}_BG. The pull-down transistor T_{DOWN} may include a drain electrode T_{DOWN}_D, a source electrode T_{DOWN}_S, a top gate electrode T_{DOWN}_TG, and a back gate electrode T_{DOWN}_BG.

Referring to the pull-up transistor T_{UP}, the drain electrode T_{UP}_D may be coupled to a high level power (or clock) signal V_{HIGH}. The source electrode T_{UP}_S may be coupled to the drain electrode T_{DOWN}_D. The back gate electrode T_{UP}_BG may receive a first input signal 1210a. In one or more embodiments, the first input signal 1210a is provided from a previous stage circuit in each respective GOA circuit. The top gate electrode T_{UP}_TG may receive the DC voltage V_{DC}.

Referring to the pull-down transistor T_{DOWN}, the source electrode T_{DOWN}_S may be coupled to a low level power (or clock) signal V_{LOW}. The drain electrode T_{DOWN}_D may be coupled to the source electrode T_{UP}_S. The back gate electrode T_{DOWN}_BG may receive a second input signal 1210b. In one or more embodiments, the second input signal 1210b is provided from a previous stage circuit in each respective GOA circuit. The top gate electrode T_{DOWN}_TG may receive the DC voltage V_{DC}.

Because the pull-up transistor T_{UP} and the pull-down transistor T_{DOWN} each receive the DC voltage V_{DC} at their respective top gate electrodes and include a back gate electrode, the pull-up transistor T_{UP} and the pull-down transistor T_{DOWN} are both type1 TFTs (i.e., a type1-A TFT 400A or a type1-C TFT 400B). In other embodiments, the pull-up transistor T_{UP} and the pull-down transistor T_{DOWN} may be type2 TFTs. The output 1212 of the GOA circuit 1208a is provided to subpixel circuits included in subpixels 250 within the display area 104. In one or more examples, the output 1212 is a scan signal (i.e., V_{SCAN1} and V_{SCAN2} described below) provided to a switching TFT of a subpixel circuit. Advantageously, as described above (FIG. 10) the DC voltage V_{DC} can be changed to tune the threshold voltages of the pull-up transistor T_{UP} and the pull-down transistor T_{DOWN}.

FIG. 12C illustrates a schematic illustration of a GOA circuit 1208b according to one or more embodiments. The first GOA circuit 1202a and the second GOA circuit 1202b may be GOA circuit 1208b.

Referring to the pull-up transistor T_{UP}, the drain electrode T_{UP}_D may be coupled to the high level power (or clock) signal V_{HIGH}. The source electrode T_{UP}_S may be coupled to the drain electrode T_{DOWN}_D. The top gate electrode T_{UP}_TG may receive the first input signal 1210a. The back gate electrode T_{UP}_BG may receive the DC voltage V_{DC}.

Referring to the pull-down transistor T_{DOWN}, the source electrode T_{DOWN}_S may be coupled to the low level power (or clock) signal V_{LOW}. The drain electrode T_{DOWN}_D may be coupled to the source electrode T_{UP}_S. The top gate electrode T_{DOWN}_TG may receive a second input signal 1210b. The back gate electrode T_{DOWN}_BG may receive the DC voltage V_{DC}.

Because the pull-up transistor T_{UP} and the pull-down transistor T_{DOWN} each receive the DC voltage V_{DC} at their respective back gate, pull-up transistor T_{UP} and the pull-down transistor T_{DOWN} are both type2 TFTs (i.e., a type2-A TFT 500A or a type2-C TFT 500B). Advantageously, as described above (FIG. 11) the DC voltage V_{DC} can be changed to tune the threshold voltages of the pull-up transistor T_{UP} and the pull-down transistor T_{DOWN}.

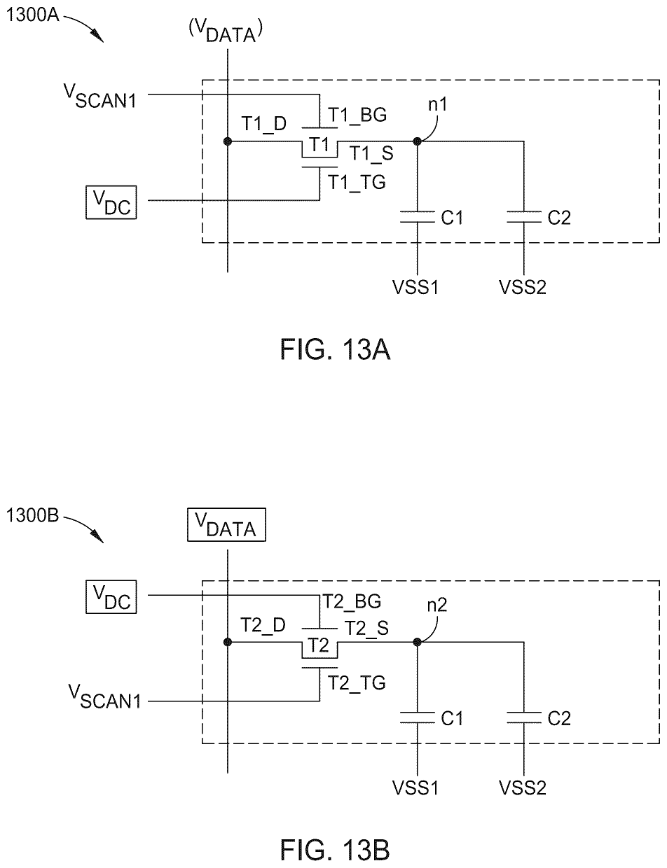

FIGS. 13A-13B illustrate schematic illustrations of a subpixel circuits, according to one or more embodiments. In one or more examples, the subpixel circuits 1300A and 1300B described in FIGS. 13A-13B are utilized in subpixels 250 of liquid crystal displays (LCDs), among other types of displays.

As illustrated in FIG. 13A, a subpixel circuit 1300A may include a switching TFT T1, a storage capacitor C1 and a loading capacitor C2. In one or more embodiments, the switching TFT T1. The switching TFT T1 may have a top gate electrode T1_TG coupled to the DC voltage V_{DC}, a back gate electrode T1_BG coupled to a scan line V_{SCAN1}, a drain electrode T1_D coupled to a data signal line V_{data} provided by the source (data) driver integrated circuit 1206, and a source electrode T1_S coupled to a node n1. Stated otherwise, the switching TFT T1 may be a type1-A TFT 400A or a type1-C TFT 400B. In one or more embodiments the scan line V_{SCAN1} may be provided by a GOA circuit (i.e., the first GOA circuit 1202a or the second GOA circuit 1202b). The source electrode T1_S may be coupled to both the storage capacitor C1 and the loading capacitor C2 via the node n1. The node n1 is coupled to the source electrode T1_S, a first side of the storage capacitor C1, and a first side of the loading capacitor C2. The storage capacitor C1 may have a first side coupled to the node n1 of switching TFT T1 and a second side coupled to a negative supply voltage V_{SS1}. The loading capacitor C2 may have a first side coupled to the node n1 and a second side coupled to negative supply voltage V_{SS2}. The first negative supply voltage V_{SS1} and the second level supply voltage V_{SS2} may have the same or different voltages. Advantageously, the switching TFT T1 includes the back gate electrode T1_BG which is not conventionally included in switching TFTs used in LEDs. As described in FIG. 10, due to the addition of the back gate electrode T1_BG, the DC voltage V_{DC} can be tuned to change (i.e., control) the threshold voltage of the switching TFT T₁ so that the threshold voltage is positive and close to zero to improve operation of the subpixel circuit 1300A without sacrificing stability.

As illustrated in FIG. 13B, a subpixel circuit 1300B may include a switching TFT T2. In one or more embodiments, the switching TFT T2. The switching TFT T2 may have a top gate electrode T2_TG coupled to the scan line V_{SCAN1}, a back gate electrode T2_BG coupled to the DC voltage V_{DC}, a drain electrode T2_D coupled to the data signal V_{DATA}, and a source electrode T2_S coupled to a node n2. Stated otherwise, the switching TFT T2 may be a type2-A TFT 500A or a type2-C TFT 500B. Thus, the DC voltage V_{DC} is applied to the back gate T2_BG of the switching TFT T2. The source electrode T2_S may be coupled to both the storage capacitor C1 and the loading capacitor C2 via the node n2. Thus, the source electrode T2_S is coupled to the storage capacitor C1 and the loading capacitor C2. The storage capacitor C1 may have a first side coupled to the node n2 and a second side coupled to the negative supply voltage V_{SS1}. The loading capacitor C2 may have a first side coupled to the node n2 and a second side coupled to the negative supply voltage V_{SS2}. The storage capacitor C1 holds the source voltage of the switching TFT T2. As described in FIG. 11, due to the addition of the back gate electrode T2_BG, the DC voltage V_{DC} can be tuned to change (i.e., control) the threshold voltage of the switching TFT T2 so that the threshold voltage is positive and close to zero to improve operation of the subpixel circuit 1300B without sacrificing stability.

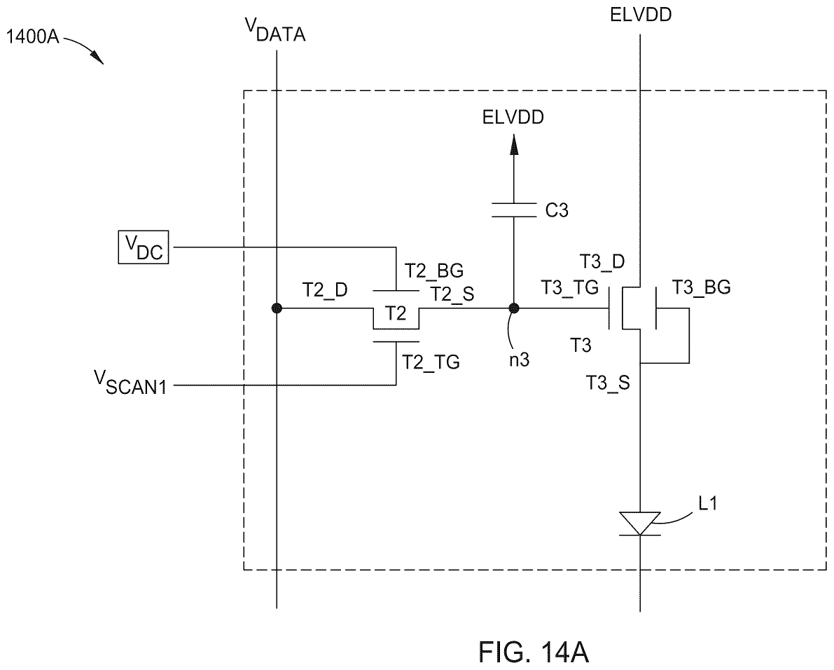

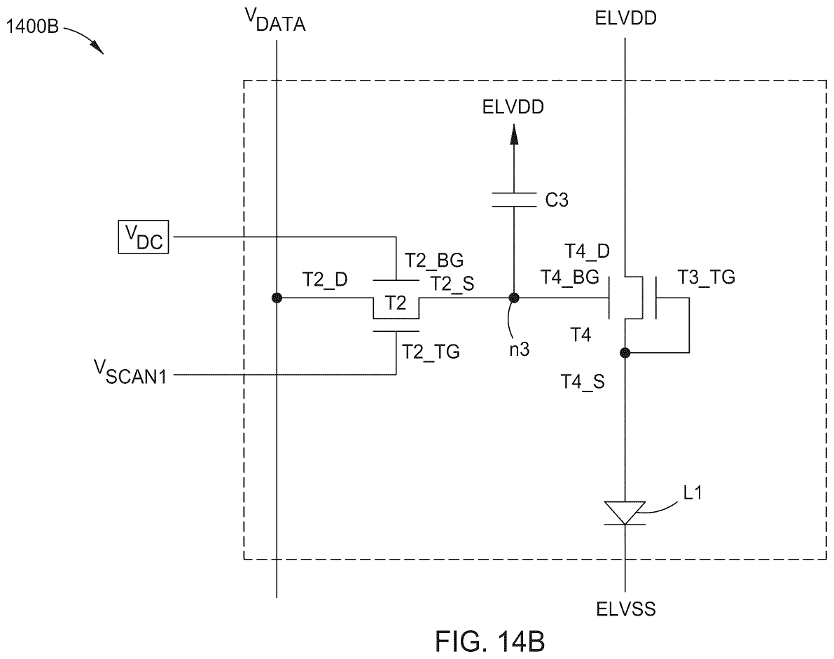

FIGS. 14A-14B illustrate schematic illustrations of a subpixel circuits, according to one or more embodiments. In one or more examples, the subpixel circuits 1400A and 1400B described in FIGS. 14A-14B are utilized in organic light emitting diode (OLED) displays, among other types of displays.

As illustrated in FIG. 14A, a subpixel circuit 1400A includes the switching TFT T2, a storage capacitor C3, a driving TFT T3 and an OLED L1. As noted above, the switching TFT T2 may be a type2-A TFT 500A or a type2-C TFT 500B. The top gate electrode T2_TG of the switching TFT T2 is coupled to the scan line V_{SCAN1}. The back gate electrode T2_BG is coupled to the DC voltage V_{DC}. The drain electrode T2_D is coupled to the data line V_{DATA}. The source electrode T2_S is coupled to a node n3.

The driving TFT T3 may include a top gate electrode T3_TG, a drain electrode T3_D, a source electrode T3_S, and a back gate electrode T3_BG. The top gate electrode T3_TG may be coupled to the node n3. The source electrode T3_S may be coupled to an anode of the OLED L1 and the back gate electrode T3_BG. The drain electrode T3_D may be coupled to a positive supply voltage ELVDD. The driving TFT T3 may have a type5-A TFT 800A or a type5-C TFT 800B.

The storage capacitor C3 may be disposed between the switching TFT T2 and the driving TFT T3. A first side of the storage capacitor C3 may be coupled to the node n3. Stated otherwise, the first side of the storage capacitor C3, the top gate electrode T3_TG of the driving TFT T3, and the source electrode T2_S of the switching TFT T2 are coupled to each other via node n3. A second side of the storage capacitor C3 may be coupled to a positive supply voltage ELVDD.

When a select signal appears on the scan line V_{SCAN1} and a data signal appears on the data line V_{DATA}, the OLED L1 is addressed or selected. The select signal on the scan line V_{SCAN1} is applied to the top gate electrode T2_TG and turns ON the switching TFT T2. The data signal of the data line V_{DATA} is applied though the switching TFT T2 to the top gate electrode T3_TG, turning ON the driving TFT T3 according to the amplitude or duration of the data signal. The driving TFT T3 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T1 is turned OFF. Thus, the storage capacitor C3 is able to maintain (store) the value of the data signal V_{DATA} even while the switching TFT T2 is OFF. In some embodiments, the second side of the storage capacitor C3 may be coupled to the anode of the OLED L1 or the source electrode T3_S of the driving TFT T3. The cathode of the OLED L1 may be connected to a negative supply voltage ELVSS.

As noted above, supplying the DC voltage V_{DC} to the back gate electrode T2_BG allows for the threshold voltage of the switching TFT T3 to be tuned using the DC voltage V_{DC} so that the threshold voltage is positive and close to zero to improve operation of the subpixel circuit 1300A without sacrificing stability.

As illustrated in FIG. 14B, a subpixel circuit 1400B includes the switching TFT T2, the storage capacitor C3, a driving TFT T4, the storage capacitor C3 and the OLED L1. As noted above the switching TFT T2 may be a type2-A TFT 500A or a type2-C TFT 500B. The driving TFT T4. The driving TFT T4 may include a back gate electrode T4_BG, a source electrode T4_S, a top gate electrode T4_TG, and a drain electrode T4_D. The back gate electrode T4_BG and the source electrode T2_S may both be coupled to the node n3. The source electrode T4_S may be coupled to an anode of the OLED L1 and the top gate electrode T4_TG. The drain electrode T4_D may be coupled to the positive supply voltage ELVDD. Thus, the driving TFT T4 may be a type6-A TFT 900A or a type6-C TFT 900B.

The storage capacitor C3 may be disposed between the switching TFT T2 and the driving TFT T4. The first side of the storage capacitor C3 may be coupled to the node n3. Stated otherwise, the first side of the storage capacitor C3, the back gate electrode T4_BG of the driving TFT T4, and the source electrode T2_S of the switching TFT T2 may each be coupled via the node n3. A second side of the storage capacitor C3 may be coupled to the positive supply voltage ELVDD.

When a select signal appears on the scan line V_{SCAN1} and a data signal appears on the data line V_{DATA}, the OLED L1 is addressed or selected. The select signal on the scan line V_{SCAN1} is applied to the top gate electrode T2_TG and turns ON the switching TFT T2. The data signal of the data line V_{DATA} is applied though the switching TFT T2 to the back gate electrode T4_BG, turning ON the driving TFT T4 according to the amplitude or duration of the data signal. The driving TFT T4 then supplies power, generally in the form of a driving current, to the OLED L1. The brightness of the light generated by the OLED L1 may depend on the amount of current and/or duration of current supplied. The storage capacitor C3 memorizes the voltage on the data line VDATA after the switching TFT T1 is turned OFF. Thus, the storage capacitor C3 is able to maintain (store) the value of the data signal VDATA even while the switching TFT T2 is OFF. In other embodiments, the second side of the storage capacitor C3 may be coupled to the anode of the OLED L1 or the source electrode T4_S of the driving TFT T4. The cathode of the OLED L1 may be connected to the negative supply voltage ELVSS.

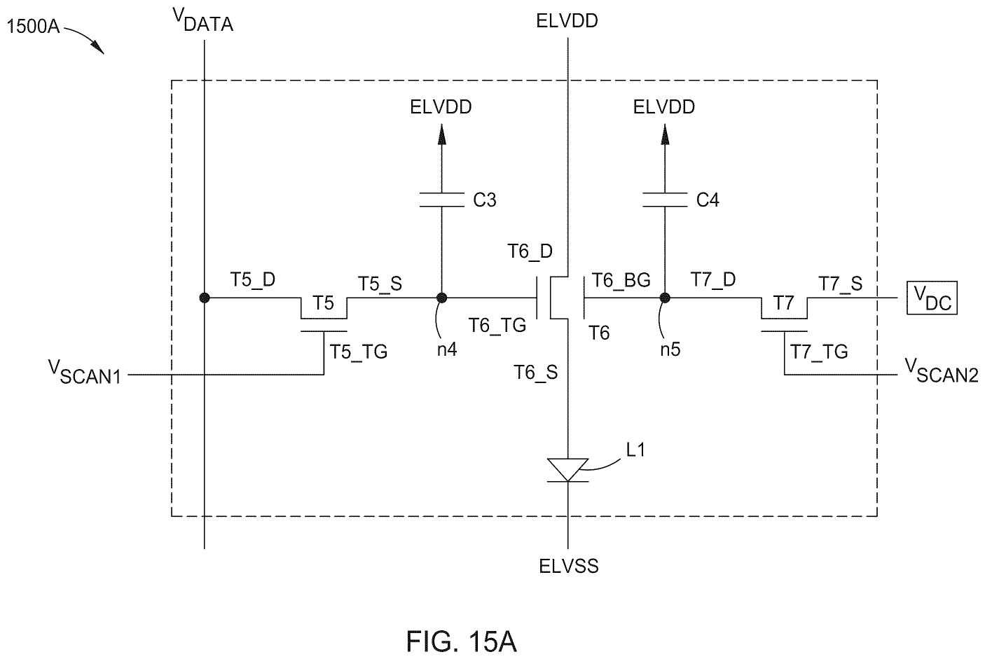

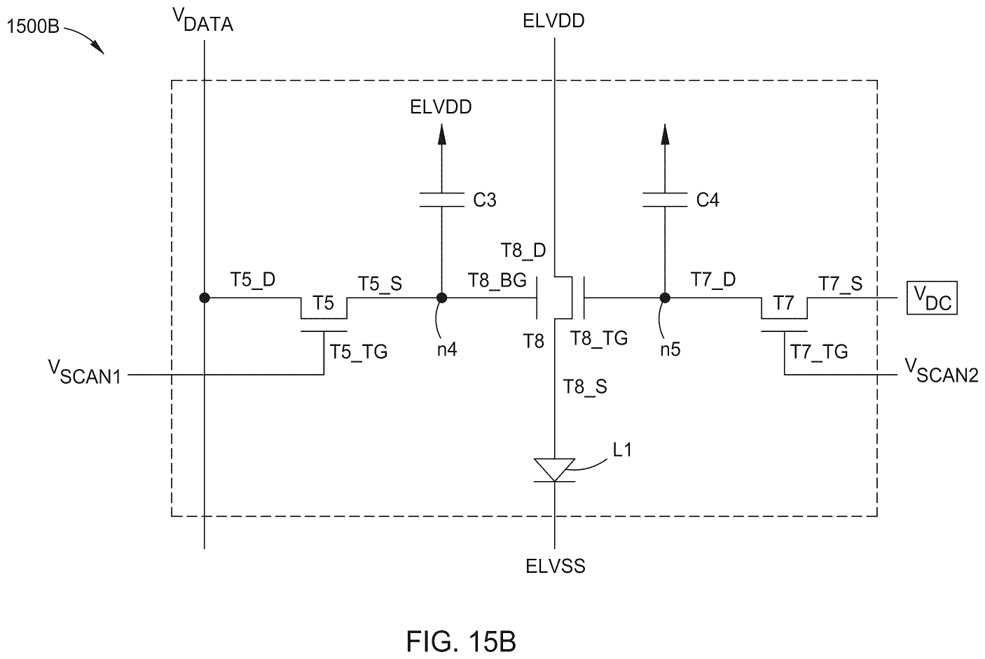

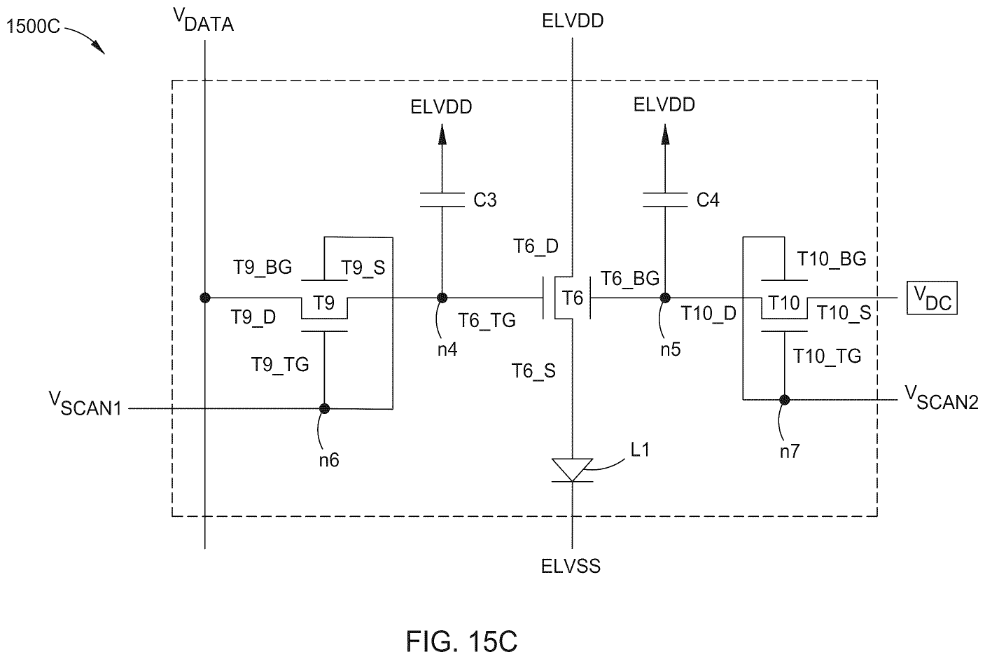

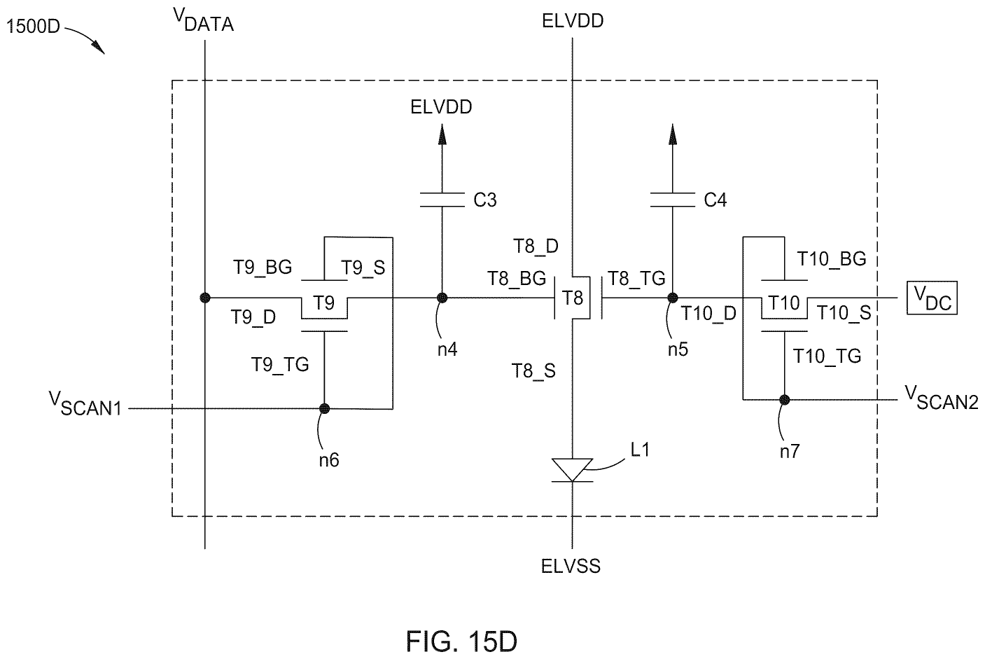

In one or more embodiments, subpixel circuits used in organic light emitting diode (OLED) displays can include a driving TFT that is coupled to a DC voltage V_{DC} through a switching TFT. The driving TFT may include a top gate electrode and a back gate electrode. As noted above, the DC voltage V_{DC} may be used to control and tune the threshold voltage of the driving TFT. To ensure that the DC voltage V_{DC} is provided to the top gate/back gate electrode (depending on the type) while the switching TFT is switching between an ON and OFF state, a capacitor may be disposed between the driving and switching TFT that is configured to hold (store) the DC voltage V_{DC}. FIGS. 15A-15C, 16A-16B, and 17A-17G illustrate subpixel circuits that include a driving TFT that is coupled to a DC voltage V_{DC} through a switching TFT.

FIGS. 15A-15D illustrate schematic illustrations of subpixel circuits, according to one or more embodiments. In one or more examples, the subpixel circuits 1500A-1500D described in FIGS. 15A-15D are utilized in organic light emitting diode (OLED) displays, among other types of displays.

As illustrated in FIG. 15A, a subpixel circuit 1500A includes a switching TFT T5, the storage capacitor C3, a driving TFT T6, a switching TFT T7, a storage capacitor C4, and the OLED L1. The switching TFT T5 may include a source electrode T5_S, a top gate electrode T5_TG, and a drain electrode T5_D. The drain electrode T5_D may be coupled to the data line V_{DATA}. The top gate electrode T5_TG may be coupled to the scan line V_{SCAN1}. The source electrode T5_S may be coupled to a node n4. Thus, the switching TFT T5 may be a type4-B TFT 700A or a type4-D TFT 700B.

The driving TFT T6 may include a top gate electrode T6_TG, a source electrode T6_S, a back gate electrode T6_BG, and a drain electrode T6_D. The top gate electrode T6_TG may be coupled to the node n4. The drain electrode T6_D may be coupled to the positive supply voltage ELVDD. The source electrode T6_S may be coupled to an anode of the OLED L1. The back gate electrode T6_BG may be coupled to a node n5. Thus, the driving TFT T6 may be a type2-A TFT 500A or a type2-C TFT 500B.

The switching TFT T7. The switching TFT T7 may include a source electrode T7_S, a top gate electrode T7_TG, and a drain electrode T7_D. The drain electrode T7_D may be coupled (also be coupled to) the node n6. The top gate electrode T7_TG may be coupled to a scan line V_{SCAN2}. The source electrode T7_S may be coupled to the DC voltage V_{DC}. The switching TFT T7 may be a type4-B TFT 700A or a type4-D TFT 700B. As noted above, the DC voltage V_{DC} is supplied to the back gate electrode T6_BG through the switching TFT T7 which allows for the threshold voltage of the driving TFT T6 to be tuned using the DC voltage V_{DC} so that the threshold voltage of the driving TFT T6 is positive and close to zero. However, during operation when the switching TFT T7 is in the OFF state, the back gate electrode T6_BG would be disconnected from the DC voltage V_{DC}. The storage capacitor C4 is disposed between the switching TFT T7 and driving capacitor T6.

The storage capacitor C4 may be disposed between the driving TFT T6 and the switching TFT T7. The first side of the storage capacitor C4 may be coupled to a node n5. Stated otherwise, the first side of the storage capacitor C4 is coupled to the back gate electrode T6_BG of the driving TFT T6 and the drain electrode T7_D of the switching TFT T7 via the node n5 A second side of the storage capacitor C4 may be coupled to the positive supply voltage ELVDD. When a select signal appears on the scan line V_{SCAN2}, the select signal on the scan line V_{SCAN2} is applied to the top gate electrode T7_TG and turns ON the switching TFT T7. The DC voltage V_{DC} is applied though the switching TFT T7 to the back gate electrode T6_BG, turning ON the driving TFT T6. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T6 during operation even if the switching TFT T7 is OFF. In other embodiments, the second side of the storage capacitor C4 may be coupled to the anode of the OLED L1 or the source electrode T6_S of the driving TFT T6.

The storage capacitor C3 may be disposed between the switching TFT T5 and the driving TFT T6. The first side of the storage capacitor C3 may be coupled to the node n4. Stated otherwise, the first side of the storage capacitor C3 may be coupled to the driving TFT T6 and the source electrode T5_S via the node n4. A second side of the storage capacitor C3 may be coupled to the positive supply voltage. When a select signal appears on the scan line V_{SCAN1} and a data signal appears on the data line VDATA, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

In other embodiments, the second side of the storage capacitor C3 may be coupled to the anode of the OLED L1 or the source electrode T6_S of the driving TFT T6. The cathode of the OLED L1 may be connected to the negative supply voltage ELVSS. Advantageously, the storage capacitor C3 is able to store the data signal V_{DATA} so that the top gate electrode T6_TG receives the data signal V_{DATA} even when the switching TFT T5 is in the OFF state.

As illustrated in FIG. 15B, a subpixel circuit 1500B includes the switching TFT T5, the storage capacitor C3, a driving TFT T8, the switching TFT T7, the storage capacitor C4, and the OLED L1.

The driving TFT T8 may include a top gate electrode T8_TG, a source electrode T8_S, a back gate electrode T8_BG, and a drain electrode T8_D. The back gate electrode T8_BG may be coupled the node n4. The source electrode T5_S of the switching TFT T5 is also coupled to the node n4. The drain electrode T8_D may be coupled to the positive supply voltage ELVDD. The source electrode T8_S may be coupled to the anode of the OLED L1. The top gate electrode T8_TG may be coupled to the node n5. Thus the driving TFT T8 may be a type1-A TFT 400A or a type1-C TFT 400B.

The storage capacitor C4 may be disposed between the driving TFT T8 and the switching TFT T7. The first side of the storage capacitor C4 may be coupled to the node n5. Stated otherwise, the first side of the storage capacitor C4 may be coupled to the top gate electrode T8_TG of the driving TFT T8 and the drain electrode T7_D of the switching TFT T7 via the node n5. A second side of the storage capacitor C4 may be coupled to the positive supply voltage. As noted above, the DC voltage V_{DC} is supplied to the top gate electrode T8_TG through the switching TFT T7 which allows for the threshold voltage of the driving TFT T8 to be tuned using the DC voltage V_{DC} so that the threshold voltage is positive and close to zero. However, during operation when the switching TFT T7 is in the OFF state, the top gate electrode T8_TG would be disconnected from the DC voltage V_{DC}. Therefore, the storage capacitor C4 is disposed between the switching TFT T7 and driving TFT T8.

Additionally, when a select signal appears on the scan line V_{SCAN2}, the select signal on the scan line V_{SCAN2} is applied to the top gate electrode T7_TG and turns ON the switching TFT T7. The DC voltage V_{DC} is applied though the switching TFT T7 to the top gate electrode T8_TG, turning ON the driving TFT T8. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T8 during operation even if the switching TFT T7 is OFF. In other embodiments, the second side of the storage capacitor C4 may be coupled to the anode of the OLED L1 or the source electrode T8_S of the driving TFT T8.

The storage capacitor C3 may be disposed between the switching TFT T5 and the driving TFT T8. The first side of the storage capacitor C3 may be coupled to the node n4. The first side of the storage capacitor C3 may be coupled to the back gate electrode T8_BG of the driving TFT T8 and the source electrode T5_S of the switching TFT T5 via the node n4. A second side of the storage capacitor C3 may be coupled to the positive supply voltage. When a select signal appears on the scan line V_{SCAN1} and a data signal appears on the data line V_{DATA}, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the back gate electrode T8_BG, turning ON the driving TFT T8 according to the amplitude or duration of the data signal. The driving TFT T8 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF. In other embodiments, the second side of the storage capacitor C3 may be coupled to the anode of the OLED L1 or the source electrode T8_S of the driving TFT T8. The cathode of the OLED L1 may be connected to the negative supply voltage ELVSS.

As illustrated in FIG. 15C, a subpixel circuit 1500C includes a switching TFT T9, the storage capacitor C3, the driving TFT T6, a switching TFT T10, the storage capacitor C4, and the OLED L1. The switching TFT T9 may include a source electrode T9_S, a top gate electrode T9_TG, a drain electrode T9_D, and a back gate electrode T9_BG. The drain electrode T9_D may be coupled a data line V_{DATA}. The top gate electrode T9_TG may be coupled a node n6. The source electrode T9_S may be coupled to the node n4. The back gate electrode T9_BG may also be coupled to the node n6. The node n6 may also be coupled to the scan line V_{SCAN1}. Thus, the back gate electrode T9_BG, the top gate electrode T9_TG, and the scan line V_{SCAN1} are coupled to one another via the node n6. The switching TFT T9 may be a type3-A TFT 600A or a type3-C TFT 600B.

The switching TFT T10 may include a source electrode T10_S, a top gate electrode T10_TG, a drain electrode T10_D, and a back gate electrode T10_BG. The drain electrode T10_D may be coupled to the node n5. The top gate electrode T10_TG may be coupled a node n7. The source electrode T10_S may be coupled to the DC voltage V_{DC}. The back gate electrode T10_BG may be coupled to the node n7. The scan line V_{SCAN2} may also be coupled to the node n7. The back gate electrode T10_BG, the top gate electrode T10_TG and the scan line V_{SCAN2} are all coupled via the node n7. The switching TFT T10 may be a type3-A TFT 600A or a type3-C TFT 600B.

As noted above, the DC voltage V_{DC} is supplied to the back gate electrode T6_BG through the switching TFT T10, which allows for the threshold voltage of the driving TFT T6 to be tuned using the DC voltage V_{DC} so that the threshold voltage is positive and close to zero. However, during operation when the switching TFT T10 is in the OFF state, the back gate electrode T6_BG would be disconnected from the DC voltage V_{DC}. Therefore, the storage capacitor C4 is disposed between the switching TFT T10 and driving TFT T6.

The storage capacitor C4 may be disposed between the driving TFT T6 and the switching TFT T10. The first side of the storage capacitor C4 may be coupled to the node n5. The first side of the storage capacitor C4, the back gate electrode T6_BG of the driving TFT T6, and the drain electrode T10_D of the switching TFT T10 may be coupled via node n5 A second side of the storage capacitor C4 may be coupled to the positive supply voltage. When a select signal appears on the scan line V_{SCAN2}, the select signal on the scan line V_{SCAN2} is applied to the top gate electrode T10_TG and the back gate electrode T10_BG, and turns ON the switching TFT T10. The DC voltage V_{DC} is applied though the switching TFT T10 to the back gate electrode T6_BG, turning ON the driving TFT T6. The storage capacitor C4 memorizes the DC voltage V_{DC} after the switching TFT T10 is turned OFF. Thus, the storage capacitor C4 is able to maintain (store) the value of the DC voltage V_{DC} even while the switching TFT T10 is OFF. Advantageously, the storage capacitor C4 is able to store (i.e., charge) the DC voltage V_{DC} so that the DC voltage V_{DC} is continuously applied to the driving TFT T6 during operation even if the switching TFT T10 is OFF. In other embodiments, the second side of the storage capacitor C4 may be coupled to the anode of the OLED L1 or the source electrode T6_S of the driving TFT T6.

The storage capacitor C3 may be disposed between the switching TFT T9 and the driving TFT T6. The first side of the storage capacitor C3 may be coupled to the node n4. The first side of the storage capacitor C3, the top gate electrode T6_TG of the driving TFT T6 and the source electrode T9_S of the switching TFT T9 may be coupled via node n4. A second side of the storage capacitor C3 may be coupled to the positive supply voltage. When a select signal appears on the scan line V_{SCAN1} and a data signal appears on the data line V_{DATA}, the OLED L1 is addressed or selected. The select signal on the scan line V_{SCAN1} is applied to the top gate electrode T9_TG and the back gate electrode T9_BG and turns ON the switching TFT T9. The data signal of the data line V_{DATA} is applied though the switching TFT T9 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T9 is turned OFF. Thus, the storage capacitor C3 is able to maintain (store) the value of the data signal V_{DATA} even while the switching TFT T9 is OFF. In other embodiments, the second side of the storage capacitor C3 may be coupled to the anode of the OLED L1 or the source electrode T6_S of the driving TFT T6. The cathode of the OLED L1 may be connected to the negative supply voltage ELVSS.

Furthermore, because the switching TFT T9 and the switching TFT T10 include back gate electrodes, more current can be applied to the subpixel circuit 1500C improving the processing speed of the subpixel circuit 1500C.

As illustrated in FIG. 15D, a subpixel circuit 1500D includes the switching TFT T9, the storage capacitor C3, the driving TFT T8, the switching TFT T10, the storage capacitor C4, and the OLED L1.

As noted above, the DC voltage V_{DC} is supplied to the top gate electrode T8_TG through the switching TFT T10 which allows for the threshold voltage of the driving TFT T8 to be tuned using the DC voltage V_{DC} so that the threshold voltage of the driving TFT T8 is positive and close to zero. However, during operation when the switching TFT T10 is in the OFF state, the top gate electrode T8_TG would be disconnected from the DC voltage V_{DC}. Therefore, the storage capacitor C4 is disposed between the switching TFT T7 and driving capacitor T8.

The storage capacitor C4 may be disposed between the driving TFT T8 and the switching TFT T10. The first side of the storage capacitor C4 may be coupled a node n5. The top gate electrode T8_TG of the driving TFT T8 and the drain electrode T10_D of the switching TFT T10 are also coupled to the node n5. Stated otherwise, the first side of the storage capacitor C4, the top gate electrode T8_TG of the driving TFT T8, and the drain electrode T10_D of the switching TFT T10 are coupled via node n5. A second side of storage capacitor C4 may be coupled to the positive supply voltage. When a select signal appears on the scan line V_{SCAN2}, the select signal on the scan line V_{SCAN2} is applied to the top gate electrode T10_TG and the back gate electrode T10_BG, and turns ON the switching TFT T10. The DC voltage V_{DC} is applied though the switching TFT T10 to the top gate electrode T8_TG, turning ON the driving TFT T8. The storage capacitor C4 memorizes the DC voltage V_{DC} after the switching TFT T10 is turned OFF. Thus, the storage capacitor C4 is able to maintain (store) the value of the DC voltage V_{DC} even while the switching TFT T10 is OFF. Advantageously, the storage capacitor C4 is able to store (i.e., charge) the DC voltage V_{DC} so that the DC voltage V_{DC} is continuously applied to the driving TFT T8 during operation even if the switching TFT T10 is OFF. In other embodiments, the second side of the storage capacitor C4 may be coupled to the anode of the OLED L1 or the source electrode T8_S of the driving TFT T8.

The storage capacitor C3 may be disposed between the switching TFT T9 and the driving TFT T8. The first side of the storage capacitor C3 may be coupled to the node n4. The source electrode T9_S of the switching TFT T9 and the back gate electrode T8_BG of the driving TFT T8 are also connected to the node n4. Stated differently, the first side of the storage capacitor C3, the source electrode T9_S of the switching TFT T9, and the back gate electrode T8_BG of the driving TFT T8 are coupled via node n4. A second side of the storage capacitor C3 may be coupled to the positive supply voltage. When a select signal appears on the scan line V_{SCAN1} and a data signal appears on the data line V_{DATA}, the OLED L1 is addressed or selected. The select signal on the scan line V_{SCAN1} is applied to the top gate electrode T9_TG and the back gate electrode T9_BG and turns ON the switching TFT T9. The data signal of the data line V_{DATA} is applied though the switching TFT T9 to the back gate electrode T8_BG, turning ON the driving TFT T8 according to the amplitude or duration of the data signal. The driving TFT T8 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T9 is turned OFF. Thus, the storage capacitor C3 is able to maintain (store) the value of the data signal V_{DATA} even while the switching TFT T9 is OFF. In other embodiments, the second side of the storage capacitor C3 may be coupled to the anode of the OLED L1 or the source electrode T8_S of the driving TFT T8. The cathode of the OLED L1 may be connected to the negative supply voltage ELVSS.

As noted above, because the switching TFT T9 and the switching TFT T10 include back gate electrodes, more current can be applied to the subpixel circuit 1500C improving the processing speed of the subpixel circuit 1500C.

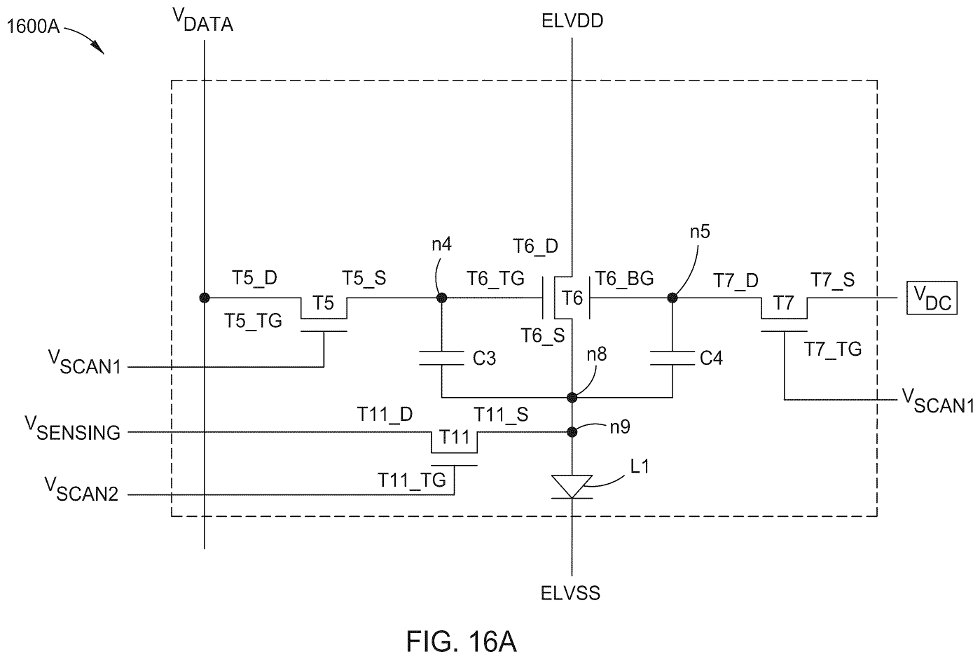

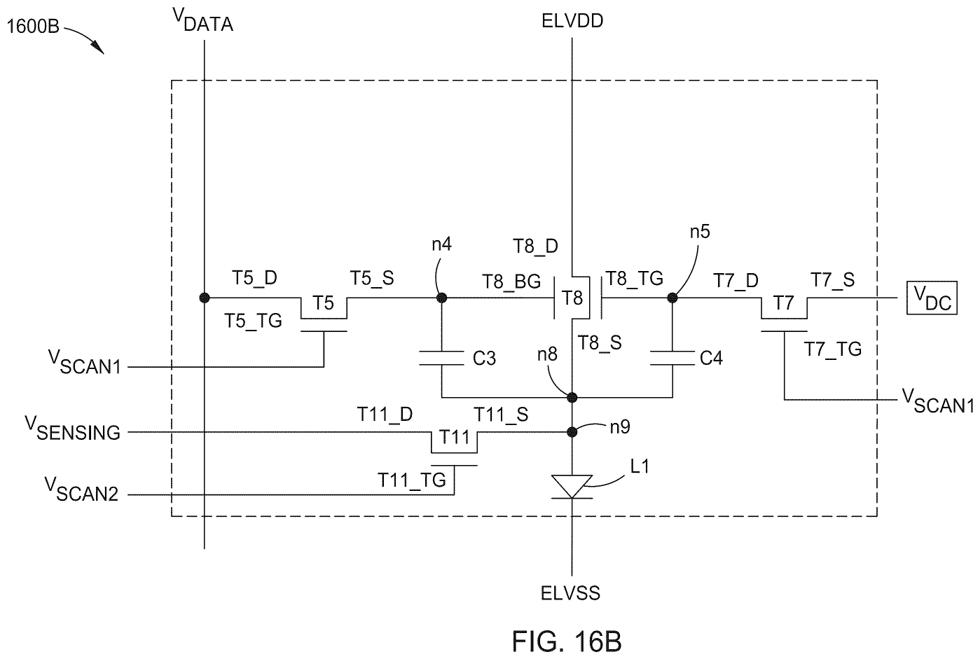

FIGS. 16A-16B illustrate schematic illustrations of a subpixel circuits, according to one or more embodiments. In one or more examples, the subpixel circuits 1600A and 1600B described in FIGS. 16A-16B are utilized in organic light emitting diode (OLED) displays, among other types of displays.

As illustrated in FIG. 16A, a subpixel circuit 1600A includes the switching TFT T5, the storage capacitor C3, the driving TFT T6, the switching TFT T7, the storage capacitor C4, a switching TFT T11 and the OLED L1. Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n4. The switching TFT T5 may be a type4-B TFT 700A or a type4-D TFT 700B.

Referring to the driving TFT T6, the top gate electrode T6_TG may be coupled to the node n4. The drain electrode T6_D may be coupled to the positive supply voltage ELVDD. The source electrode T6_S may be coupled to a node n8. The back gate electrode T6_BG may be coupled to the node n5. Thus the driving TFT T6 may be a type2-A TFT 500A or a type2-C TFT 500B.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}. The switching TFT T7 may be a type4-B TFT 700A or a type4-D TFT 700B. As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T10 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via node n5. A second side of the storage capacitor C4 may be coupled to a node n8. When a select signal appears on the scan line V_{SCAN1}, the select signal on the scan line V_{SCAN1} is applied to the top gate electrode T7_TG and turns ON the switching TFT T7. The DC voltage V_{DC} is applied though the switching TFT T7 to the back gate electrode T6_BG, turning ON the driving TFT T6. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T6 during operation even if the switching TFT T7 is OFF.

The first side of the storage capacitor C3 may be coupled to the node n4. The first side of the storage capacitor C3, the top gate electrode T6_TG of the driving TFT T6, and the source electrode T5_S of the switching TFT T5 are coupled via the node n4. A second side of the storage capacitor C3 may be coupled to the node n8. When a select signal appears on the scan line V_{SCAN1} and a data signal appears on the data line V_{DATA}, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

The switching TFT T11 may include a source electrode T11_S, a top gate electrode T11_TG, and a drain electrode T11_D. The drain electrode T11_D may be coupled to a voltage sensing line V_{SENSING}. The voltage sensing line V_{SENSING} is provided from the source (data) driver integrated circuit 1206. The top gate electrode T11_TG may be coupled to the scan line V_{SCAN2}. The source electrode T11_S may be coupled to a node n9. Thus, the switching TFT T11 may be a type4-B TFT 700A or a type4-D TFT 700B.

In one or more embodiments, the second side of the storage capacitor C3, the source electrode T6_S of the driving TFT T6, and the second side of the storage capacitor C4 are coupled via node n8. The node n9 may also be further coupled to the node n8 and the anode of the OLED L1. Therefore, the second side of the storage capacitor C3, the source electrode T6_S of the driving TFT T6, the second side of the storage capacitor C4, the source electrode T11_S of the switching TFT T11, and the anode of the OLED L1 are coupled via nodes n8 and n9.

As illustrated in FIG. 16B, a subpixel circuit 1600B includes the switching TFT T5, the storage capacitor C3, the driving TFT T8, the switching TFT T7, the storage capacitor C4, a switching TFT T11 and the OLED L1. Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n4.

Referring to the driving TFT T8, the back gate electrode T8_BG may be coupled to the node n4. The drain electrode T8_D may be coupled to the positive supply voltage ELVDD. The source electrode T8_S may be coupled to the node n8. The top gate electrode T8_TG may be coupled to the node n5.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

As noted above, the DC voltage V_{DC} is supplied to the top gate electrode T8_TG through the switching TFT T7, which allows for the threshold voltage of the driving TFT T8 to be tuned using the DC voltage V_{DC} so that the threshold voltage is positive and close to zero. However, during operation when the switching TFT T7 is in the OFF state, the top gate electrode T8_TG would be disconnected from the DC voltage V_{DC}. Therefore, the storage capacitor C4 is disposed between the switching TFT T8 and driving TFT T7.

The storage capacitor C4 may be disposed between the driving TFT T8 and the switching TFT T7. The first side of the storage capacitor C4 may be coupled to the node n5. The first side of the storage capacitor C4, the top gate electrode T8_TG of the driving TFT T8, and the drain electrode T7_D of the switching TFT T7 may be coupled via the node n5. A second side of the storage capacitor C4 may be coupled to the node n8. When a select signal appears on the scan line V_{SCAN1}, the select signal on the scan line V_{SCAN1} is applied to the top gate electrode T7_TG and turns ON the switching TFT T7. The DC voltage V_{DC} is applied though the switching TFT T7 to the top gate electrode T8_TG, turning ON the driving TFT T8. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T8 during operation even if the switching TFT T7 is OFF.

The first side of the storage capacitor C3 may be coupled to the node n4. The first side of the storage capacitor C3, the back gate electrode T8_BG of the driving TFT T8, and the source electrode T5_S of the switching TFT T5 are coupled via the node n4. A second side of the storage capacitor C3 may be coupled to the node n8. When a select signal appears on the scan line V_{SCAN1} and a data signal appears on the data line V_{DATA}, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the back gate electrode T8_BG, turning ON the driving TFT T8 according to the amplitude or duration of the data signal. The driving TFT T8 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

Referring to the switching TFT T11, the drain electrode T11_D may be coupled to a voltage sensing line V_{SENSING}. The top gate electrode T11_TG may be coupled to the scan line V_{SCAN2}. The source electrode T11_S may be coupled to a node n9. Thus, the switching TFT T11 may be a type4-B TFT 700A or a type4-D TFT 700B.

In one or more embodiments, the second side of the storage capacitor C3, the source electrode T8_S of the driving TFT T8, and the second side of the storage capacitor C4 are coupled via node n8. The node n9 may also be further coupled to the node n8 and the anode of the OLED L1. Therefore, the second side of the storage capacitor C3, the source electrode T8_S of the driving TFT T8, the second side of the storage capacitor C4, the source electrode T11_S of the switching TFT T11, and the anode of the OLED L1 are coupled via nodes n8 and n9.

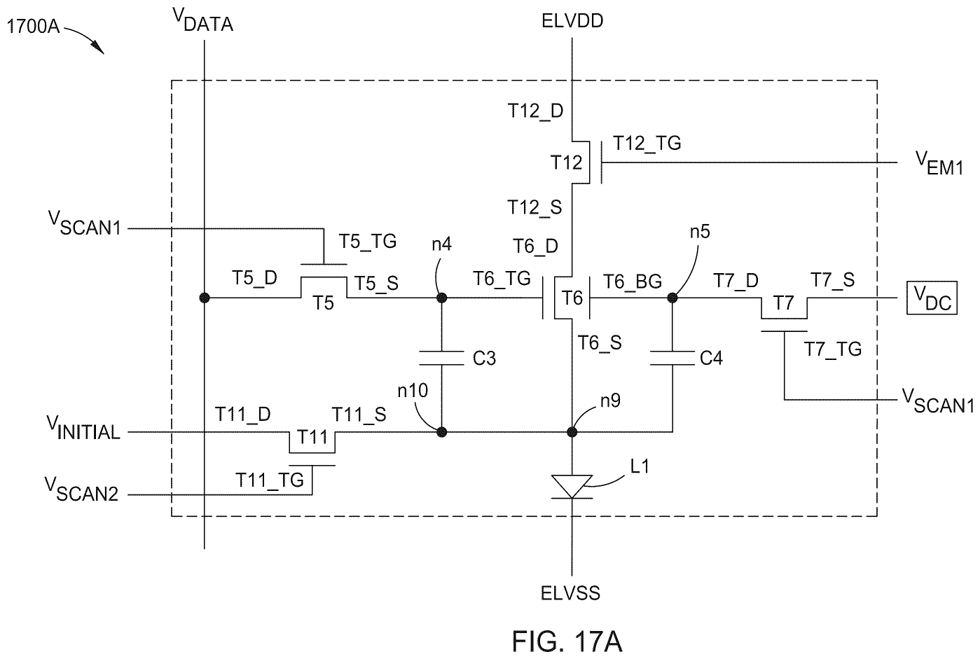

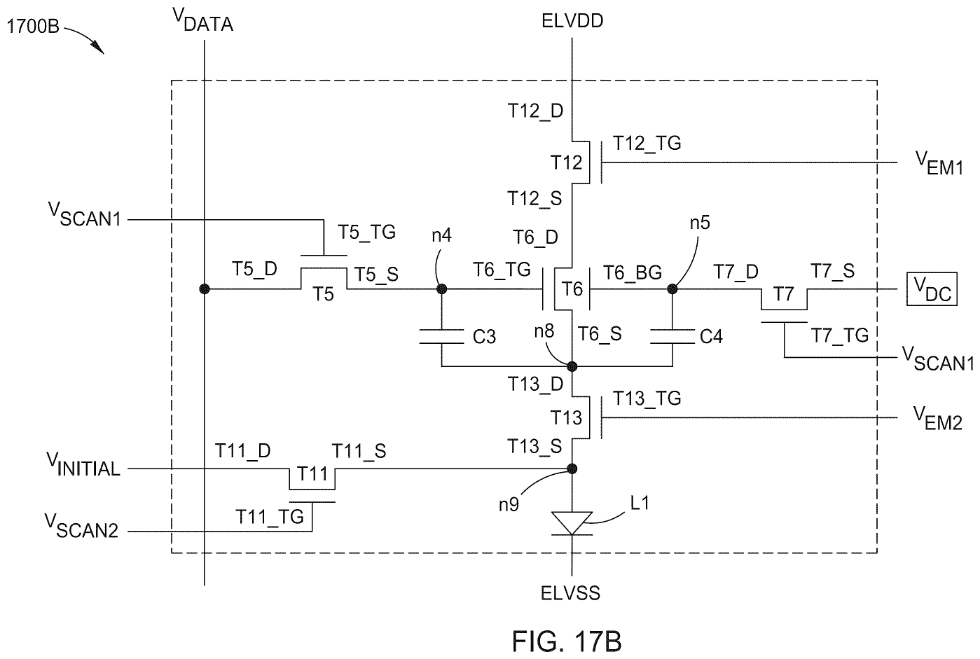

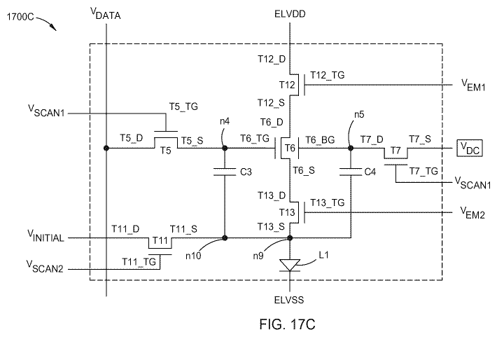

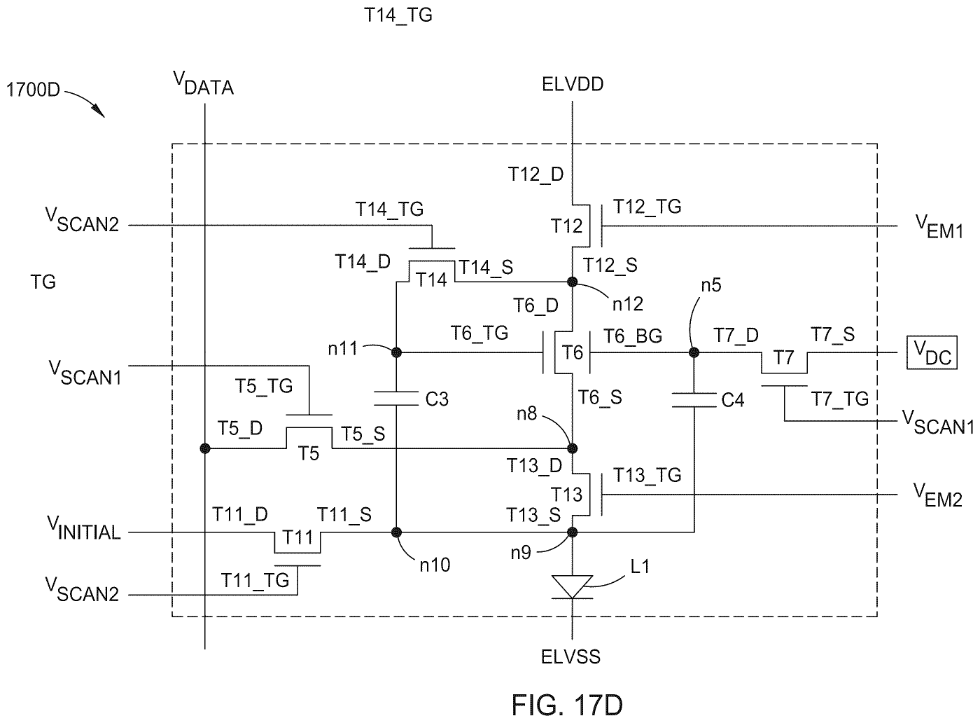

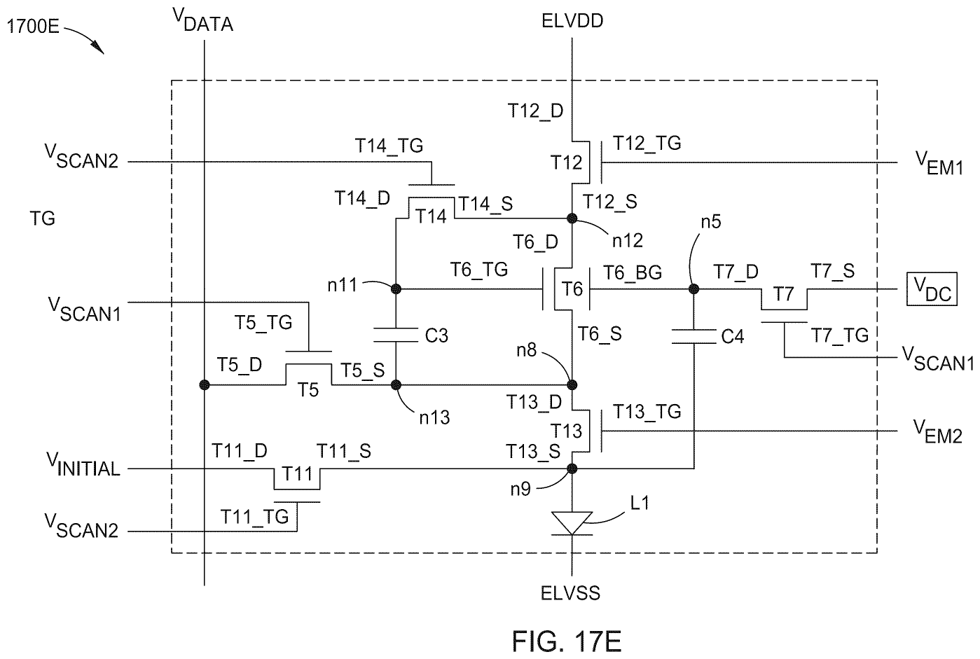

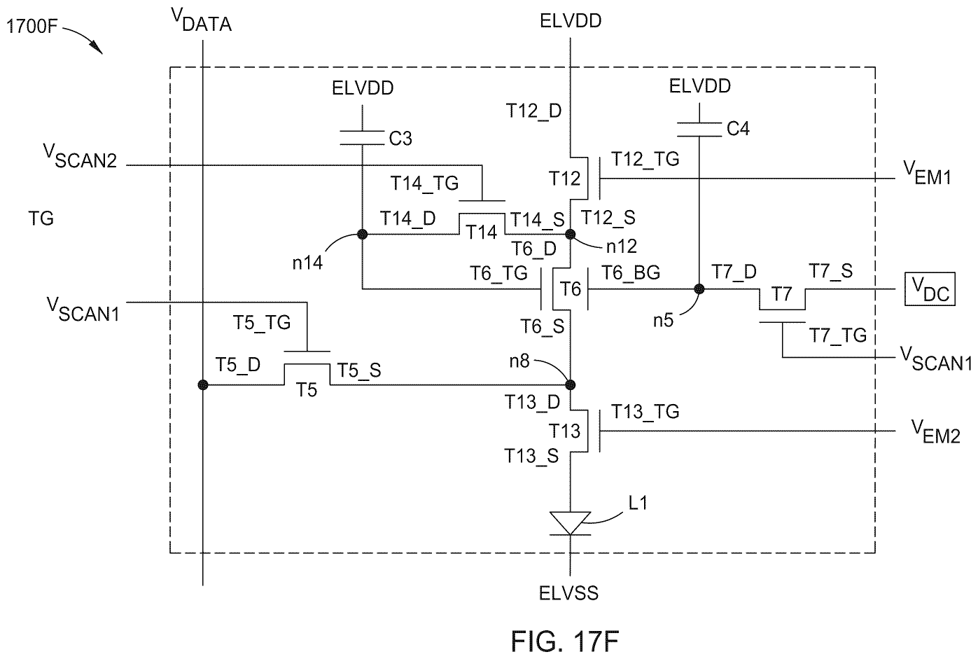

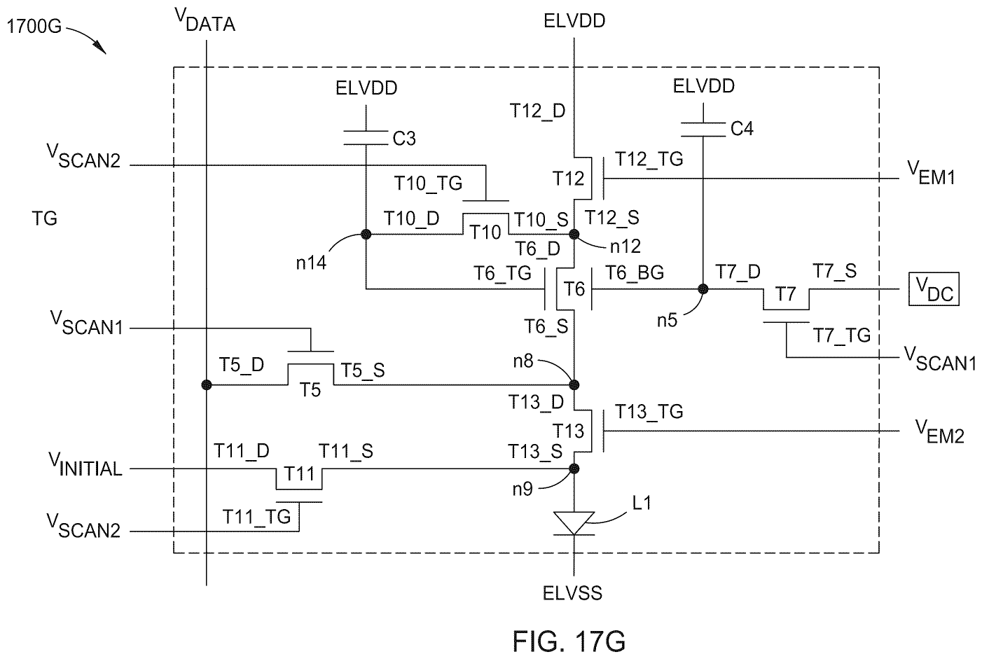

FIGS. 17A-17G illustrate schematic illustrations of a subpixel circuits, according to one or more embodiments. In one or more examples, the subpixel circuits 1700A-1700G described in FIGS. 17A-17G are utilized in organic light emitting diode (OLED) displays, among other types of displays.

As illustrated in FIG. 17A, a subpixel circuit 1700A includes the switching TFT T5, the storage capacitor C3, the driving TFT T6, the switching TFT T7, the storage capacitor C4, the switching TFT T11, a switching TFT T12 and the OLED L1.

The switching TFT T12 may include a source electrode T12_S, a top gate electrode T12_TG, and a drain electrode T12_D. The drain electrode T12_D may be coupled to the positive supply voltage ELVDD. The top gate electrode T12_TG may be coupled to a frequency modulated voltage signal VEM₁. The source electrode T12_S may be coupled to the drain electrode T6_D of the driving TFT T6. The switching TFT T12 may be a type4-B TFT 700A or a type4-D TFT 700B.

Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n4. The switching TFT T5 may be a type4-B TFT 700A or a type4-D TFT 700B.

Referring to the driving TFT T6, the top gate electrode T6_TG may be coupled to the node n4. The drain electrode T6_D may be coupled the source electrode T12_S of the switching TFT T12. The source electrode T6_S may be coupled to the node n9. The back gate electrode T6_BG may be coupled to the node n5. The driving TFT T6 may be a type2-A TFT 500A or a type2-C TFT 500B.

Referring to the switching TFT T7, the drain electrode T7_D may be coupled the node n5. The top gate electrode T7_TG may be coupled to the scan line V_{SCAN1}. The source electrode T7_S may be coupled to the DC voltage V_{DC}. The switching TFT T7 may be a type4-B TFT 700A or a type4-D TFT 700B.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via node n5. A second side of the storage capacitor C4 may be coupled to the node n9. When a select signal appears on the scan line V_{SCAN1}, the select signal on the scan line V_{SCAN1} is applied to the top gate electrode T7_TG and turns ON the switching TFT T7. The DC voltage V_{DC} is applied though the switching TFT T7 to the back gate electrode T6_BG, turning ON the driving TFT T6. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T6 during operation even if the switching TFT T7 is OFF.

The first side of the storage capacitor C3 may be coupled to the node n4. The first side of the storage capacitor C3, the top gate electrode T6_TG of the driving TFT T6, and the source electrode T5_S of the switching TFT T5 are coupled via the node n4. A second side of the storage capacitor C3 may be coupled to a node n10. When a select signal appears on the scan line V_{SCAN1} and a data signal appears on the data line V_{DATA}, the OLED L1 is addressed or selected. The select signal on the scan line V_{SCAN1} IS applied to the top gate electrode T5_TG and turns ON the switching TFT T5. The data signal of the data line V_{DATA} is applied though the switching TFT T5 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

Referring to the switching TFT T11, the drain electrode T11_D may be coupled to an initial voltage signal V_{INITAL} provided from a respective GOA circuit. The top gate electrode T11_TG may be coupled the voltage sensing line V_{SCAN2}. The source electrode T11_S may be coupled to the node n10. The source electrode T11_S and the second side of the switching TFT C3 are coupled via node n10. The node n10 may be further coupled to the node n9. The switching TFT T11 may be a type4-B TFT 700A or a type4-D TFT 700B. In one or more embodiments, the initial voltage signal V_{INITAL} is provided by a respective GOA circuit or the a source (data) driver integrated circuit 1206 and is used to discharge built-up charge in the anode of the OLED L1 through switching TFT T11 for a better display image at the initial stage of pixel circuit operation.

In one or more embodiments, the second side of the storage capacitor C3, the source electrode T6_S of the driving TFT T6, and the second side of the storage capacitor C4 are coupled via node n9. The node n9 may also be further coupled to the node n10 and the anode of the OLED L1. Therefore, the second side of the storage capacitor C3, the source electrode T6_S of the driving TFT T6, the second side of the storage capacitor C4, the source electrode T11_S of the switching TFT T11, and the anode of the OLED L1 are coupled via nodes n9 and n10.

As illustrated in FIG. 17B, a subpixel circuit 1700B includes the switching TFT T5, the storage capacitor C3, the driving TFT T6, the switching TFT T7, the storage capacitor C4, the switching TFT T11, a switching TFT T12, a switching TFT T13, and the OLED L1. In one or more embodiments, the positive supply voltage ELVDD is delivered (or not delivered) to the based on the state of the switching TFT T12. If the switching TFT T12 is OFF the connection between the positive supply voltage ELVDD and the driving TFT T6 is disconnected, there is no current flowing though driving TFT T6, and no current flowing through OLED L1.

The switching TFT T13 may include a source electrode T13_S, a top gate electrode T13_TG, and a drain electrode T13_D. The drain electrode T13_D may be coupled to the node n8. The source electrode T13_S may be coupled to the node n9. The top gate electrode T13_TG may be coupled to a frequency modulated voltage signal VEM₂. The switching TFT T13 may be a type4-B TFT 700A or a type4-D TFT 700B. In one or more embodiments, the current in driving TFT T6 can be delivered (or not delivered) to OLED L1 based on the state of the switching TFT T13 controlled by the frequency modulated voltage signal VEM₂. If the switching TFT T13 is OFF, the connection between OLED L1 and driving TFT T6 is disconnected and there is no current flowing from driving TFT T6 to OLED L1.

Referring to the switching TFT T12, the top gate electrode T12_TG may be coupled to a frequency modulated voltage signal VEM₁. The drain electrode T12_D may be coupled to the positive supply voltage ELVDD. The source electrode T12_S may be coupled to the drain electrode T6_D of the switching TFT T6.

Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n4.

Referring to the driving TFT T6, the top gate electrode T6_TG may be coupled to the node n4. The drain electrode T6_D may be coupled the source electrode T12_S of the switching TFT T12. The source electrode T6_S may be coupled to the node n8. The back gate electrode T6_BG may be coupled to the node n5.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via node n5. A second side of the storage capacitor C4 may be coupled to the node n8. The second side of the storage capacitor C4, the source electrode T6_S of the driving TFT T6, the second side of the storage capacitor C3, and the drain electrode T13_D of the switching TFT T13 are coupled via the node n8. When a select signal appears on the scan line V_{SCAN1}, the select signal on the scan line V_{SCAN1} is applied to the top gate electrode T7_TG and turns ON the switching TFT T7. The DC voltage V_{DC} is applied though the switching TFT T7 to the back gate electrode T6_BG, turning ON the driving TFT T6. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T6 during operation even if the switching TFT T7 is OFF.

The first side of the storage capacitor C3 may be coupled to the node n4. The first side of the storage capacitor C3, the top gate electrode T6_TG of the driving TFT T6, and the source electrode T5_S of the switching TFT T5 are coupled via the node n4. A second side of the storage capacitor C3 may be coupled to a node n8. When a select signal appears on the scan line V_{SCAN1} and a data signal appears on the data line V_{DATA}, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

Referring to the switching TFT T11, the drain electrode T11_D may be coupled to V_{INITAL}. The top gate electrode T11_TG may be coupled the voltage sensing line V_{SCAN2}.

In one or more embodiments, the node n9 may also be further coupled to the anode of the OLED L1. Therefore, source electrode T11_S of the switching TFT T11, the source electrode T13_S of the switching TFT T13, and the anode of the OLED L1 are coupled via the node n9.

As illustrated in FIG. 17C, a subpixel circuit 1700C includes the switching TFT T5, the storage capacitor C3, the driving TFT T6, the switching TFT T7, the storage capacitor C4, the switching TFT T11, a switching TFT T12, the switching TFT T13, and the OLED L1.

Referring to the switching TFT T13, the drain electrode T13_D may be coupled to the source electrode T6_S. The source electrode T13_S may be coupled to a node n9. The top gate electrode T13_TG may be coupled to the frequency modulated voltage signal VEM₂.

Referring to the switching TFT T12, the top gate electrode T12_TG may be coupled to a frequency modulated voltage signal (VEM₁). The drain electrode T12_D may be coupled to the positive supply voltage ELVDD. The source electrode T12_S may be coupled to the drain electrode T6_D of the driving TFT T6.

Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n4.

Referring to the driving TFT T6, the top gate electrode T6_TG may be coupled to the node n4. The drain electrode T6_D may be coupled the source electrode T12_S of the switching TFT T12. The source electrode T6_S may be coupled to the drain T13_D of the switching TFT T13. The back gate electrode T6_BG may be coupled to the node n5.

Referring to the switching TFT T7, the drain electrode T7_D may be coupled the node n5. The top gate electrode T7_TG may be coupled to the scan line V_{SCAN1}. The source electrode T7_S may be coupled to the DC voltage V_{DC}.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via the node n5. A second side of the storage capacitor C4 may be coupled to the node n9. When a select signal appears on the scan line V_{SCAN1}, the select signal on the scan line V_{SCAN1} is applied to the top gate electrode T7_TG and turns ON the switching TFT T7. The DC voltage V_{DC} is applied though the switching TFT T7 to the back gate electrode T6_BG, turning ON the driving TFT T6. The storage capacitor C4 memorizes the DC voltage V_{DC} after the switching TFT T7 is turned OFF. Thus, the storage capacitor C4 is able to maintain (store) the value of the DC voltage V_{DC} even while the switching TFT T7 is OFF. Advantageously, the storage capacitor C4 is able to store (i.e., charge) the DC voltage V_{DC} so that the DC voltage V_{DC} is continuously applied to the driving TFT T6 during operation even if the switching TFT T7 is OFF.

The first side of the storage capacitor C3 may be coupled to the node n4. The first side of the storage capacitor C3, the top gate electrode T6_TG of the driving TFT T6, and the source electrode T5_S of the switching TFT T5 are coupled via the node n4. A second side of the storage capacitor C3 may be coupled to the node n10. When a select signal appears on the scan line V_{SCAN1} and a data signal appears on the data line V_{DATA}, the OLED L1 is addressed or selected. The select signal on the scan line V_{SCAN1} is applied to the top gate electrode T5_TG and turns ON the switching TFT T5. The data signal of the data line V_{DATA} is applied though the switching TFT T5 to the top gate electrode T6_TG, turning ON the driving TFT T6 according to the amplitude or duration of the data signal. The driving TFT T6 then supplies power, generally in the form of a driving current, to the OLED L1. The brightness of the light generated by the OLED L1 may depend on the amount of current and/or duration of current supplied. The storage capacitor C3 memorizes the voltage on the data line V_{DATA} after the switching TFT T5 is turned OFF. Thus, the storage capacitor C3 is able to maintain (store) the value of the data signal V_{DATA} even while the switching TFT T5 is OFF.

Referring to the switching TFT T11, the drain electrode T11_D may be coupled to V_{INITAL}. The top gate electrode T11_TG may be coupled the voltage sensing line V_{SCAN2}. The source electrode T11_S may be coupled to the node n10. The source electrode T11_S of the switching TFT T11 and the second side of the storage capacitor C3 are coupled via node n10. The node n10 may be further coupled to the node n9.

In one or more embodiments, the node n9 may also be further coupled to the anode of the OLED L1. Therefore, source electrode T11_S of the switching TFT T11, the source electrode T13_S of the switching TFT T13, the second side of the storage capacitor C4, and the anode of the OLED L1 are coupled via node n9.

As illustrated in FIG. 17D, a subpixel circuit 1700D includes the switching TFT T5, the storage capacitor C3, the driving TFT T6, the switching TFT T7, the storage capacitor C4, the switching TFT T11, a switching TFT T12, the switching TFT T13, a switching TFT T14 and the OLED L1.

The switching TFT T14 may include a source electrode T14_S, a top gate electrode T14_TG, and a drain electrode T14_D. The drain electrode T14_D may be coupled to a node n11. The source electrode T14_S may be coupled to a node n12. The top gate electrode T14_TG may be coupled to the scan line V_{SCAN2}. The switching TFT T14 may be a type4-B TFT 700A or a type4-D TFT 700B. In one or more embodiments, the state (i.e., ON or OFF) of switching TFT T14 is set by the scan line V_{SCAN2} from the GOA circuits to connect or disconnect top gate electrode T6_TG and the drain electrode T6_D during operation. This can be done especially for low threshold voltage (Vₜₕ) compensation to flow constant current from driving TFT T6 to OLED L1 for a better display image.

Referring to the switching TFT T12, the top gate electrode T12_TG may be coupled to the frequency modulated voltage signal VEM₁. The drain electrode T12_D may be coupled to the positive supply voltage ELVDD. The source electrode T12_S may be coupled to a node n12.

Referring to the driving TFT T6, the top gate electrode T6_TG may be coupled to the node n11. The drain electrode T6_D may be coupled the node n12. The source electrode T6_S may be coupled to the node n8. The back gate electrode T6_BG may be coupled to the node n5. Thus, the source electrode T12_S of the switching TFT T12, the source electrode T14_S of the switching TFT T14, and the drain electrode T6_D of the driving TFT T6 are coupled via the node n12.

Referring to the switching TFT T13, the drain electrode T13_D may be coupled to the node n8. The source electrode T13_S may be coupled to a node n9. The top gate electrode T13_TG may be coupled to the frequency modulated voltage signal VEM₂.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n8. Thus, the source electrode T5_S of the switching TFT T5, the drain electrode T13_D of the drain electrode T12, and the source electrode T6_S of the driving electrode T6 are coupled via node n8.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via the node n5. A second side of the storage capacitor C4 may be coupled to the node n9. Advantageously, the storage capacitor C4 is able to store (i.e., charge) the DC voltage V_{DC} so that the DC voltage V_{DC} is continuously applied to the driving TFT T6 during operation even if the switching TFT T7 is in the OFF state.

The first side of the storage capacitor C3 may be coupled to the node n11. The first side of the storage capacitor C3, the top gate electrode T6_TG of the driving TFT T6, and the drain electrode T14_D of the switching TFT TD are coupled via the node n11. The second side of the storage capacitor C3 may be coupled to the node n10. Advantageously, the storage capacitor C3 is able to store the data signal V_{DATA} so that the top gate electrode T6_TG receives the data signal V_{DATA} even when the switching TFT T5 is in the off state.

Referring to the switching TFT T11, the drain electrode T11_D may be coupled to V_{INITAL}. The top gate electrode T11_TG may be coupled the voltage sensing line V_{SCAN2}. The source electrode T11_S may be coupled to the node n10. The source electrode T11_S of the switching TFT T11, and the second side of the storage capacitor C3 are coupled via node n10. The node n10 may be further coupled to the node n9.

In one or more embodiments, the node n9 may also be further coupled to the anode of the OLED L1. Therefore, source electrode T11_S of the switching TFT T11, the source electrode T13_S of the switching TFT T13, the second side of the storage capacitor C4 and the anode of the OLED L1 are coupled via node n9.

As illustrated in FIG. 17E, a subpixel circuit 1700E includes the switching TFT T5, the storage capacitor C3, the driving TFT T6, the switching TFT T7, the storage capacitor C4, the switching TFT T11, a switching TFT T12, the switching TFT T13, a switching TFT T14 and the OLED L1.

Referring to switching TFT T14, the drain electrode T14_D may be coupled to the node n11. The source electrode T14_S may be coupled to the node n12. The top gate electrode T14_TG may be coupled to the scan line V_{SCAN2}.

Referring to the switching TFT T12, the top gate electrode T12_TG may be coupled to the frequency modulated voltage signal VEM₁. The drain electrode T12_D may be coupled to the positive supply voltage ELVDD. The source electrode T12_S may be coupled to the node n12.

Referring to the driving TFT T6, the top gate electrode T6_TG may be coupled to the node n11. The drain electrode T6_D may be coupled the node n12. The source electrode T6_S may be coupled to a node n8. The back gate electrode T6_BG may be coupled to the node n5. Thus, the source electrode T12_S of the switching TFT T12, the source electrode T14_S of the switching TFT T14, and the drain electrode T6_D of the driving TFT T6 are coupled via the node n12.

Referring to the switching TFT T13, the drain electrode T13_D may be coupled to the node n8. The source electrode T13_S may be coupled to the node n9. The top gate electrode T13_TG may be coupled to the frequency modulated voltage signal VEM₂.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

Referring to the switching TFT T5, the drain electrode T5_D may be coupled to the data line V_{DATA}. The top gate electrode T5_TG may be coupled to the scan line V_{SCAN1}. The source electrode T5_S may be coupled to a node n13.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

The storage capacitor C4 may be disposed between the driving TFT T6 and the switching TFT T7. The first side of the storage capacitor C4 may be coupled to the node n5. The first side of the storage capacitor C4, the back gate electrode T6_BG of the driving TFT T6, and the drain electrode T7_D of the switching TFT T7 may be coupled via the node n5. A second side of the storage capacitor C4 may be coupled to the node n9. Advantageously, the storage capacitor C4 is able to store (i.e., charge) the DC voltage V_{DC} so that the DC voltage V_{DC} is continuously applied to the driving TFT T6 during operation even if the switching TFT T7 is in the OFF state.

The first side of the storage capacitor C3 may be coupled to the node n11. The first side of the storage capacitor C3, the top gate electrode T6_TG of the driving TFT T6, and the drain electrode T14_D of the switching TFT T14 are coupled via the node n11. The second side of the storage capacitor C3 may be coupled to a node n13. The node n13 may be further coupled to the node n8. Advantageously, the storage capacitor C3 is able to store the data signal V_{DATA} so that the top gate electrode T6_TG receives the data signal V_{DATA} even when the switching TFT T5 is in the off state.

Referring to the switching TFT T11, the drain electrode T11_D may be coupled to V_{INITAL}. The top gate electrode T11_TG may be coupled the voltage sensing line V_{SCAN2}. The source electrode T11_S may be coupled to the node n9. The node n9 may be further coupled to the anode of OLED L1. Therefore, source electrode T11_S of the switching TFT T11, the source electrode T13_S of the switching TFT T13, the second side of the storage capacitor C4 and the anode of the OLED L1 are coupled via node n9.

As illustrated in FIG. 17F, a subpixel circuit 1700F includes the switching TFT T5, the storage capacitor C3, the driving TFT T6, the switching TFT T7, the storage capacitor C4, a switching TFT T12, a switching TFT T14 and the OLED L1.

Referring to switching TFT T14, the drain electrode T14_D may be coupled to a node n14. The source electrode T14_S may be coupled to the node n12. The top gate electrode T14_TG may be coupled to the scan line V_{SCAN2}.

Referring to the driving TFT T6, the top gate electrode T6_TG may be coupled to the node n14. The drain electrode T6_D may be coupled the node n12. The source electrode T6_S may be coupled to the node n8. The back gate electrode T6_BG may be coupled to a node n5. Thus, the source electrode T12_S of the switching TFT T12, the source electrode T14_S of the switching TFT T14, and the drain electrode T6_D are coupled via the node n12.

Referring to the switching TFT T12, the top gate electrode T12_TG may be coupled to the frequency modulated voltage signal VEM₁. The drain electrode T12_D may be coupled to the positive supply voltage ELVDD. The source electrode T12_S may be coupled to the node n12.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

Referring to the storage capacitor C4, a first side of the storage capacitor C4 may be coupled to the positive supply voltage ELVDD. A second side of the storage capacitor C4 may be coupled to the node n5. The second side of the storage capacitor C4, the back gate electrode T6_BG of the driving TFT T6, and the drain electrode T7_D of the switching TFT T7 are coupled via node n5. Advantageously, the storage capacitor C4 is able to store (i.e., charge) the DC voltage V_{DC} so that the DC voltage V_{DC} is continuously applied to the driving TFT T6 during operation even if the switching TFT T7 is in the OFF state.

The first side of the storage capacitor C3 may be coupled to positive supply voltage ELVDD. The second side of the storage capacitor C3 may be coupled to the node n14. The second side of the storage capacitor C3, the top gate electrode T6_TG of the driving TFT T6, and the drain electrode T14_D of switching TFT T14 may be coupled via the node n14. Advantageously, the storage capacitor C3 is able to store the data signal V_{DATA} so that the top gate electrode T6_TG receives the data signal V_{DATA} even when the switching TFT T5 is in the off state.

Referring to the switching TFT T13, the drain electrode T13_D may be coupled to the node n8. The source electrode T13_S may be coupled to the anode of the OLED L1. The top gate electrode T13_TG may be coupled to a frequency modulated voltage signal VEM₂.

As illustrated in FIG. 17G, a subpixel circuit 1700G includes the switching TFT T5, the storage capacitor C3, the driving TFT T6, the switching TFT T7, the storage capacitor C4, the switching TFT T11, a switching TFT T12, the switching TFT T13, the switching TFT T10 and the OLED L1.

Referring to switching TFT T10, the drain electrode T10_D may be coupled to the node n14. The source electrode T10_S may be coupled to the node n12. The top gate electrode T10_TG may be coupled to the scan line V_{SCAN2}.

Referring to the switching TFT T12, the top gate electrode T12_TG may be coupled to the frequency modulated voltage signal VEM₁. The drain electrode T12_D may be coupled to the positive supply voltage ELVDD. The source electrode T12_S may be coupled to the node n12.

Referring to the driving TFT T6, the top gate electrode T6_TG may be coupled to the node n14. The drain electrode T6_D may be coupled the node n12. The source electrode T6_S may be coupled to the node n8. The back gate electrode T6_BG may be coupled to the node n5. Thus, the source electrode T12_S of the switching TFT T12, the source electrode T10_S of the switching TFT T10, and the drain electrode T6_D are coupled via the node n12.

Referring to the switching TFT T7, the drain electrode T7_D may be coupled to the node n5. The top gate electrode T7_TG may be coupled to the scan line V_{SCAN1}. The source electrode T7_S may be coupled to the DC voltage V_{DC}.

As noted above, the DC voltage V_{DC} is supplied to the back gate electrode T6_BG through the switching TFT T7, which allows for the threshold voltage of the driving TFT T6 to be tuned using the DC voltage V_{DC} so that the threshold voltage is positive and close to zero. However, during operation when the switching TFT T7 is in the OFF state, the back gate electrode T6_BG would be disconnected from the DC voltage V_{DC}. Therefore, the storage capacitor C4 is disposed between the switching TFT T7 and driving TFT T6.

Referring to the storage capacitor C4, a first side of the storage capacitor C4 may be coupled to the positive supply voltage ELVDD. A second side of the storage capacitor C4 may be coupled to the node n5. The second side of the storage capacitor C4, the back gate electrode T6_BG of the driving TFT T6, and the drain electrode T7_D of the switching TFT T7 are coupled via the node n5. Advantageously, the storage capacitor C4 is able to store (i.e., charge) the DC voltage V_{DC} so that the DC voltage V_{DC} is continuously applied to the driving TFT T6 during operation even if the switching TFT T7 is in the OFF state.

Referring to the switching TFT T13, the drain electrode T13_D may be coupled to the node n8. The source electrode T13_S may be coupled to a node n9. The top gate electrode T13_TG may be coupled to a frequency modulated voltage signal VEM₂.

Referring to the switching TFT T5, the drain electrode T5_D may be coupled to the data line V_{DATA}. The top gate electrode T5_TG may be coupled to the scan line V_{SCAN1}. The source electrode T5_S may be coupled to the node n8. Thus, the source electrode T5_S of the switching TFT T5, the drain electrode T13_D of the drain electrode T12, and the source electrode T6_S of the driving electrode T6 are coupled via node n8.

The first side of the storage capacitor C3 may be coupled to the positive supply voltage ELVDD. The second side of the storage capacitor C3 may be coupled to the node n14. Thus, the second side of the storage capacitor C3, the top gate electrode T6_TG of the driving TFT T6, and the drain electrode T10_D of switching TFT T10 may be coupled via the node n14. Advantageously, the storage capacitor C3 is able to store the data signal V_{DATA} so that the top gate electrode T6_TG receives the data signal V_{DATA} even when the switching TFT T5 is in the off state. In one or more embodiments, the state (i.e., ON or OFF) of switching TFT T10 is set by the scan line V_{SCAN2} from the GOA circuits to connect or disconnect top gate electrode T6_TG and the drain electrode T6_D during operation. This can be done especially for low threshold voltage (Vₜₕ) compensation to flow constant current from driving TFT T6 to OLED L1 for a better display image.

Referring to the switching TFT T11, the drain electrode T11_D may be coupled to V_{INITAL}. The top gate electrode T11_TG may be coupled the voltage sensing line V_{SCAN2}. The source electrode T11_S may be coupled to the node n9. The node n9 may be further coupled to the anode of OLED L1. Therefore, source electrode T11_S of the switching TFT T11, the source electrode T13_S of the switching TFT T13, the second side of the storage capacitor C4 and the anode of the OLED L1 are coupled via node n9.

What is claimed is:

1. A circuit comprising:
a switching thin film transistor (TFT), the switching TFT having a threshold voltage that is based on a value of a direct current voltage (DC) voltage;
a driving TFT coupled to the switching TFT;
a storage capacitor disposed between the switching TFT and the driving TFT; and
an organic light-emitting diode (OLED) having an anode coupled to the driving TFT.

2. The circuit of claim 1, wherein:
a drain electrode of the switching TFT is coupled to a data signal line; and
a source electrode of the switching TFT is coupled to a node that is further coupled to a top gate electrode of the driving TFT and the storage capacitor;
a source electrode of the driving TFT is coupled to the anode of the OLED; and
a back gate electrode of the driving TFT is coupled to the source electrode of the driving TFT.

3. The circuit of claim 1, wherein:
a drain electrode of the switching TFT is coupled to a data signal line;
a source electrode of the switching TFT is coupled to a node that is further coupled to a top gate electrode of the driving TFT and the storage capacitor;
a source electrode of the driving TFT is coupled to the anode of the OLED; and
a back gate electrode of the driving TFT is coupled to the source electrode of the switching TFT.

4. The circuit of claim 1, wherein a top gate electrode of the switching TFT is coupled to a gate driver on array (GOA) circuit comprising:
a pull-up TFT having a back gate electrode coupled to the DC voltage; and
a pull-down TFT coupled to the pull-up TFT, the pull-down TFT having a back gate electrode coupled to the DC voltage.

5. The circuit of claim 1, wherein a top gate electrode of the switching TFT is coupled to a gate driver on array (GOA) circuit comprising:
a pull-up TFT having a top gate electrode coupled to the DC voltage; and
a pull-down TFT coupled to the pull-up TFT, the pull-down TFT having a top gate electrode coupled to the DC voltage.

6. A circuit comprising:
a first switching thin film transistor (TFT);
a second switching TFT, the second switching TFT having a threshold voltage that is based on a value of a direct current (DC) voltage;
a driving TFT coupled to the first switching TFT and the second switching TFT;
a first storage capacitor having a first side that is coupled to a first node disposed between the second switching TFT and the driving TFT; and
an organic light-emitting diode (OLED) having an anode coupled to the driving TFT.

7. The circuit of claim 6, wherein a second side of the first storage capacitor is coupled to the anode of the OLED, a positive supply voltage, or a source electrode of the driving TFT.

8. The circuit of claim 6, wherein the first side of the first storage capacitor is coupled to a drain electrode of the second switching TFT and a back gate electrode of the driving TFT via the first node.

9. The circuit of claim 8, further comprising:
a second storage capacitor coupled to a second node disposed between a source electrode of the first switching TFT and a top gate electrode of the driving TFT.

10. The circuit of claim 6, wherein the first side of the first storage capacitor is coupled to a drain electrode of the second switching TFT and a top gate electrode of the driving TFT via the first node.

11. The circuit of claim 10, further comprising:
a second storage capacitor coupled to a second node disposed between a source electrode of the first switching TFT and a back gate electrode of the driving TFT.

12. The circuit of claim 6, wherein a top gate electrode of the second switching TFT is coupled to a back gate electrode of the second switching TFT.

13. The circuit of claim 6, further comprising a third switching TFT coupled between a voltage sensing line and the anode of the OLED.

14. The circuit of claim 13, further comprising a fourth switching TFT coupled between the driving TFT and a positive supply voltage.

15. The circuit of claim 14, further comprising a fifth switching TFT coupled between the driving TFT and the anode of the OLED.

16. The circuit of claim 15, further comprising a sixth switching TFT having a source electrode coupled to a third node and a drain electrode coupled to a fourth node, wherein the third node that is further coupled to a source electrode of the fourth switching TFT and a drain electrode of the driving TFT, and the fourth node is further coupled to a top gate electrode of the driving TFT and a second capacitor.

17. The circuit of claim 6, wherein the first switching TFT and the second switching TFT are coupled to a gate driver on array (GOA) circuit comprising:
a pull-up TFT having a back gate electrode coupled to the DC voltage; and
a pull-down TFT coupled to the pull-up TFT, the pull-down TFT having a back gate electrode coupled to the DC voltage.

18. The circuit of claim 6, wherein the first switching TFT and the second switching TFT are coupled to a gate driver on array (GOA) circuit comprising:
a pull-up TFT having a top gate electrode coupled to the DC voltage; and
a pull-down TFT coupled to the pull-up TFT, the pull-down TFT having a top gate electrode coupled to the DC voltage.

19. A circuit comprising:
a switching TFT, the switching TFT having a threshold voltage that is based on a value of a direct current (DC) voltage;
a loading capacitor coupled to the switching TFT; and
a storage capacitor coupled to the switching TFT.

20. The circuit of claim 19, wherein a top gate electrode of the switching TFT is coupled to the DC voltage or a back gate electrode of the switching TFT is coupled to the DC voltage.
